(19) United States
(12) Patent Application Publication
(10) Pub. No.: US 2024/0395457 A1
(43) Pub. Date: Nov. 28, 2024

(54) Methods of Manufacturing Hybrid Magnetic Substrate, Via-based Ferrite Inductors and Transformers

(71) Applicant: Winchester Technologies, LLC, Winchester, MA (US)

(72) Inventors: Xiaoling Shi, Acton, MA (US); Hui Lu, Winchester, MA (US); Hwaider Lin, Bedford, MA (US); Nian Xiang Sun, Winchester, MA (US)

(73) Assignee: Winchester Technologies, LLC, Winchester, MA (US)

(21) Appl. No.: 18/759,287

(22) Filed: Jun. 28, 2024

Related U.S. Application Data
(63) Continuation-in-part of application No. 17/503,873, filed on Oct. 18, 2021, now Pat. No. 12,094,630.
(60) Provisional application No. 63/571,584, filed on Mar. 29, 2024.
(60) Provisional application No. 63/116,827, filed on Nov. 21, 2020.

(51) Int. Cl. H01F 41/14; B32B 5/02; B32B 5/26; B32B 37/06; B32B 37/10; B32B 37/18; C25D 5/02; C25D 5/54; C25D 7/00

(52) U.S. Cl. CPC H01F 41/14; B32B 5/024; B32B 5/262; B32B 37/06; B32B 37/10; B32B 37/182; C25D 5/022; C25D 5/54; C25D 7/001; B32B 2250/05; B32B 2250/20; B32B 2255/02; B32B 2255/20; B32B 2255/28; B32B 2260/023; B32B 2260/046; B32B 2262/101; B32B 2305/076; B32B 2305/08; B32B 2305/188; B32B 2307/7376; B32B 2309/02; B32B 2309/04; B32B 2309/105; B32B 2309/12; B32B 2311/20; B32B 2311/22; B32B 2311/30; B32B 2315/085; B32B 2363/00; B32B 2457/08

(57) ABSTRACT

A hybrid magnetic substrate manufacturing method through spin-spraying ferrite coating solutions is disclosed, wafers of various schematic slit patterns using spin-spray ferrite coating generate magnetic hybrid substrates. A ferrite via-based inductor or transformer using spin-spray manufacturing method produces quality factors greater than 625 at 50˜300 MHz. Integrated ferrite inductors of I-shaped and U-shaped copper patterns with various ferrite loops that have quality factors bigger than 700 at 50˜300 MHz are manufactured.

### CROSS-REFERENCE TO RELATED APPLICATIONS

Priority is claimed from the U.S. Provisional Patent Application No. 63/571,584, filed on Mar. 29, 2024, entitled “Via-based Ferrite Inductor and Transformer,” the entirety of which is hereby incorporated by reference. The Application is also a Continuation In Part to U.S. patent application Ser. No. 17/503,873 filed on Oct. 18, 2021, entitled “Millimeter Thick Magnetic PCB with High Relative Permeability and Devices Thereof,” the entirety of which is hereby incorporated by reference. Priority is claimed from the U.S. Provisional Patent Application No. 63/116,827, filed on Nov. 21, 2020, entitled “Millimeter thick magnetic print circuit boards (PCBs) with a high relative permeability of 50˜150 and related devices and systems”, the entirety of which is hereby incorporated by reference.

### FEDERALLY SPONSORED RESEARCH AND DEVELOPMENT

This invention was made with government support under Army contract #W31P4Q-23-C-0049 awarded by Army Contracting Command-Redstone, Redstone Arsenal, AL 35893-5280. The government has certain rights in the invention.

### BACKGROUND OF THE INVENTION

State-of-the-art integrated power supplies are Power Supply in Package (PwrSiP) with 3D heterogeneous integration of integrated magnetic inductors, interposer, UWBG GaN switches, IC chips, etc. on a PCB (printed circuit board). Power Supply on Chip (PwrSoC) is also built with all active and passive components integrated on the same chip. In such power supplies, integrated inductors often dominate in size and loss. Reducing the inductor size and improving the inductor performance are essential for PwrSoC and PwrSiP development. Presently no Commercial Off-the-Shelf (COTS) inductor materials, nor air core, can satisfactorily address the needs of future Power and Energy systems regarding power handling, efficiency, compact size, areal/volumetric inductance density, energy/power efficiency, and thermal rise. New integrated magnetic materials, inductor designs, and fabrication methods with 250 MHz or above bandwidth or operating frequencies are needed to provide high SWAP+C2 (size, weight, power, cost, and cooling).

Both ferrites and amorphous and nano-crystalline metallic magnetic materials are possible candidate materials for integrated magnetic materials for UWBG LRU applications. Yet, the need for thick, more than multi-micrometers and high operating frequencies for integrated power inductors makes amorphous and nano-crystalline metallic magnetic materials unsuitable as candidate power magnetic materials due to their high costs, low resistivity, large eddy current loss, and the challenges in integrating several-micrometer-thick amorphous and nano-crystalline metallic magnetic materials. Spin spray ferrites have been demonstrated by the inventors to meet all these challenges and constitute excellent choices for integrated magnetic materials for power electronics.

Besides the need for new integrated ferrite materials, new substrate materials, new integrated ferrite inductor designs with compact size, high inductance, low DC resistance, high current density, high energy density, high cooling capabilities, and high-quality factor >30 at the operating frequency at 250 MHz and above are needed.

Conventional soft magnetic powder core is manufactured mainly by pressing via a press machine. The press process has certain advantages in manufacturing soft magnetic core, but there are some noted shortcomings and deficiencies as described below: Firstly, the press machine is a large piece of equipment. The pressure per unit area of 1 cm² needs 15T or more to press the soft magnetic powder core. It thus needs high equipment investment and contributes to high production costs; secondly, the process requires a mold made of special material for the pressing process, which places restrictions on the production of complex shapes. Additionally, the mold is wearable and expensive, therefore limiting the speed in the development of the magnetic core; thirdly, after the pressing process, a soft magnetic core still needs additional complex processes, such as an annealing process to eliminate stress, a process to strengthen infiltration, and a chamfering process. Understandably, the production efficiency is lowered, and the labor cost is increased by these additional processes. Fourthly, the size of the product is restricted by the press machine, this process may not be suitable for the development of smaller-size magnetic core. The major limit of such soft magnetic cores made by pressing is its challenge in integration onto Si or other substrates.

A via-based ferrite inductor is a type of inductor that uses a ferrite core and via holes in a substrate to create a compact magnetic inductor. A via hole is a small opening in a Si or printed circuit board (PCB) that connects different layers of the board. A via-based ferrite inductor can be used to filter out high-frequency noise and improve the performance of electronic circuits.

The characteristics and advantages of a via-based ferrite inductor are: first, a ferrite core inductor works by allowing the flow of current to generate a magnetic field, and the change within the magnetic field results in the flowing of an opposing current. Therefore, they change the energy from electrical to magnetic and store the energy within them. Second, a ferrite core inductor has a compact size and high inductance density, with low loss, high permeability, and temperature stability, and it operates at medium and high frequency. It also provides higher inductance and complete screening. Third, a ferrite core inductor can be used in power transformers, switching circuits, Pi filters, and rod antennas. It can also be used in telecom, entertainment, and other communication systems.

There is a need to develop a novel process suitable for manufacturing smaller-sized via-based ferrite inductors.

Conventional ferrite film deposition processes use pulsed laser deposition, sputtering, molecular beam epitaxy or other physical vapor deposition technologies. But these ferrite film deposition technologies are not viable for manufacturing integrated magnetic PCBs because high temperatures (>700° C.) are needed for forming high crystalline quality ferrite materials, which is not CMOS compatible, and will damage the polymer-based PCBs. Other technologies explored include incorporation of magnetic powders inside via holes in the Si PCB substrates, which leads to complicated processes and high costs of integration.

The inventors of this patent application have developed a novel spin spray technology to deposit ferrite films on Si or PCB substrates for manufacturing integrated magnetic materials and inductors. Because spin spray deposition produces thin film geometry with fully dense nanocrystalline ferrite crystal sizes and large shape anisotropy, the deposited ferrite films on Si or PCB substrates have the potential of operating from DC to several GHz with a tunable high relative permeability of over 100 and low loss tangents. Compared to other deposition methods for ferrites, this spin-spray process is uniquely suitable for manufacturing high-quality, smaller, via-based ferrite inductors.

### SUMMARY OF THE INVENTION

Embodiments of the invention provide a novel ferrite layer formation process that is performed at a lower temperature than conventional ferrite formation processes. The ferrite formation process produces fully dense, high-permeability, and thick ferrite films, and enables mm-thick magnetic substrates with high tunable permeabilities via CMOS-compatible processes.

In one aspect of an embodiment, a ferrite layer is deposited on a substrate to form a coated substrate by spin spray deposition using the spin-spray machine developed by the inventors. During deposition, a substrate is heated on a rotation platform. Metals reactant solution and oxidizer solution are respectively provided to substrate via nozzles while the substrate is rotated. The metals solution is an aqueous solution including two or more salts, such as chlorides of iron, nickel, zinc, manganese, or other metal with a valence of two. The oxidizer solution is an aqueous solution of an oxidizing agent, such as sodium nitrite and buffer solution. In one aspect, the reactant and oxidant solutions are provided in the form of atomizing liquid droplets, promoting a more uniform temperature on the substrate.

In one aspect of an embodiment, the rotation rate, pH, fluid flow, and temperature of the heating are adjusted to achieve a desired spinel ferrite. In one example, a FR4 substrate is mounted on a 24″ disc rotating at 90 rpm. The platform on which the substrate is positioned is heated to a temperature up to 100° C.) or between room temperature to 300° C. The flow rate of the reactant and the oxidant is automated at a selected rate between 5 ml/min and 100 ml/min. The rotation rate and temperature is monitored. As such, a ferrite layer is deposited on a FR4 or other substrate. The process is particularly applicable to spin coating processes. This process may be performed at temperatures less than 300° C., and even more advantageously at temperatures below 100° C.

In another embodiment, a thin film ferrite laminate is fabricated by forming a layered substrate assembly including two or more coated FR4 substrates, each substrate having a ferrite thin film, or layer, on one or both sides of the substrate surface, and hot-pressing the ferrite-coated substrates sandwiching an adhesion layer, such as a 50 μm prepreg, to form a film ferrite laminate. As an alternative, the layered assembly is formed such that a ferrite layer on a first coated substrate contacts a thermoplastic surface of the second coated substrate. In an example, the layered assembly is formed by stacking two or more coated substrates, one on top of another.

In one aspect, the coated substrates used to form a layered assembly have substantially uniform dimensions. The surface area, shape, and thickness of the substrates are not limited. In one example, a substrate is in a circular shape that has a diameter between 1 inche and 12 inches. In another example, a substrate is rectangular with the dimensions of 1 foot by 1 foot. The thickness of the ferrite substrates may be in a range between 100 μm and 5 mm. In some cases, the thickness of one or more of the ferrite layers is between 100 μm and 1 mm.

In one embodiment, an antenna is made by using high permeability magnetic PCBs to increase the gain, efficiency, and bandwidth, while keeping the antenna size as small as conventional antennas using dielectric with high dielectric constant.

In one embodiment, a power inductor is produced by using low-temperature spin spray ferrite and which has improved inductance and quality factor at MHz frequencies over their air core counterparts by using the high permeability MnZn ferrite filmed PCBs.

Spin-spray deposition has several major advantages. Firstly, spin spray deposition is a low-cost wet chemistry synthesis process in aqueous solution at a low temperature of 90° C., an extremely low processing temperature. Spin spray ferrites have been deposited onto different substrates, including organic substrates such as PCBs, transparencies, glass, and ceramics, by the inventors of this application. The low deposition temperature enables high quality fully dense ferrite film deposition on almost any substrate, even on organic substrates such as PCBs, transparencies, Si substrates, glass, etc. with excellent adhesion. In contrast, conventional ferrite processing temperatures are in the range of >700° C., which is incompatible with PCBs, RFIC (Radio Frequency Integrated Circuit) or MMIC (Monolithic Microwave Integrated Circuit).

Secondly, spin-spray processing is a low-cost process with a high deposition rate (>1 nm/second), which is more than an order of magnitude higher than conventional vacuum deposition techniques. In addition, the spin-spray processing can deposit conformal ferrite films onto uneven surfaces, even concave or convex surfaces.

Thirdly, the inventors have successfully demonstrated that spin-spray deposition can be combined with room temperature spin coating of polyimide or photoresist for achieving thick (>10 μm) ferrite/dielectric multilayer films with excellent RF magnetic properties, low roughness and excellent film uniformity.

Lastly, the properties of these spin spray deposited ferrite films can be further tuned by changing their compositions to provide either a high positive permeability and low loss tangent, or a high imaginary permeability and large loss tangent needed for RF wave absorber applications.

Spin spray deposition is thus a viable method that is able to produce fully dense, high crystalline quality, and low-loss RF ferrites at a low temperature (<90° C.) using aqueous solutions at a low cost, enabling direct integration of high-quality RF ferrites on PCBs and Si substrates. So far, spin spray deposition is the only reported viable method that is able to produce fully dense, high crystalline quality, low-loss and thick RF ferrite films at a low temperature (<90° C.) and using low-cost aqueous solutions, which makes possible direct integration of ferrites on PCBs and RFIC and MMIC. Besides the advantages above, spin spray deposited ferrites enable thick magnetic substrates, and via inductors with low costs and excellent performances.

Ferrite films have advantages that bulk ferrite materials do not have for 0.5˜3 GHZ operation range, such as high permeability, high ferromagnetic resonance frequency, and wide operation frequency range, etc. For ferrite films applications, such as antennas or absorbers, that require ferrite films in millimeter thicknesses, it is demonstrated that such thickness can be effectively achieved using ferrite/insulator multilayers coated onto substrates through spin spray; or, alternatively, using multiple layers of ferrite coated ultra-thin substrates for making multilayer thick ferrites. While conventional sintered bulk ferrite materials, or ferrite powder in polymer matrix all have poor performance and cannot be used at 100 MHz and above. spin spray ferrite film technology can provide efficient antennas operating at 100 MHz or above.

In another embodiment, the spin-spray deposition process is applied to manufacturing via-based ferrite hybrid substrate and inductors. Substrates or wafer disks may be pre-patterned with various combinations of hole patterns, and a layer of ferrite film is subsequently spin-sprayed to the holed substrates or wafers. Substrates may be any combination of suitable materials, such as, organic (PCBs and flexible), glass, Si, SiC, GaN, etc. Any kind of compact integrated ferrite inductors and transformers may be manufactured with planar and vertical ferrite/insulator laminate of mm-thick magnetic substrates with a high relative permeability of 10˜1000 and low loss tangents at up to 400 MHZ.

### BRIEF DESCRIPTION OF DRAWINGS

FIG. 1A is a schematic of a spin-spray deposition system in accordance with this application.

FIG. 1B is an example spin-spray deposition rotation machine system in accordance to an illustrative embodiment of the invention.

FIG. 2 is an optical microscope image of 3 μm MnZn Ferrite deposit film on a 12 inch by 12 inch 100 μm thick square RF4 substrate.

FIG. 3A is a photo picture of the RFMAG26 ferromagnetic resonance spectrometer for measuring ferromagnetic resonance made by Winchester Technology LLC. The sample is placed directly above a co-planar waveguide (CPW) with an electromagnet providing a bias magnetic field parallel to the center part of the CPW where the magnetic film side is placed facing the CPW.

FIG. 3B is the ferromagnetic resonance (FMR) of the 3 μm MnZn ferrite film on the 100 μm thick FR4 substrates in FIG. 2.

FIG. 3C is the real permeability of the 3 μm MnZn ferrite film on FR4 substrate of FIG. 2, showing a high effective saturation magnetization greater than 0.8 T and high real permeability larger than 2000.

FIG. 4 is a measurement of real permeability of other referenced magnetic ferrite films on PCBs and Si in comparison to the 3 μm MnZn Ferrite films on FR4 of FIG. 2 that shows a real permeability of 2000.

FIG. 5 is a schematic of a magnetic PCB laminate with multiple layers of 3 μm MnZn-ferrite/100 μm FR4/3 μm MnZn-ferrite laminated together with epoxy glue through hot-pressing in accordance with this application.

FIG. 6A is an optical microscope image of an example 2 inch by 2 inch of 0.65 mm thickness formed by 4 layers of 3 μm MnZn-ferrite/100 μm FR4/3 μm MnZn-ferrite laminated with 50 μm prepreg through hot-pressing.

FIG. 6B is an optical microscope image of an example 2 inch by 2 inch of 1.3 mm thickness form by 8 layers of 3 μm MnZn-ferrite/100 μm FR4/3 μm MnZn-ferrite laminated with 50 μm prepreg through hot-pressing.

FIG. 7A is the FMR of the 0.65 mm thick magnetic laminate material formed by 4 layers of 3 μm MnZn-ferrite/100 μm FR4/3 μm MnZn-ferrite attached with a thin layer of 50 μm prepreg hot-pressed at 90° C.

FIG. 7B is the permeability of the 0.65 mm magnetic laminate material of FIG. 7A showing a permeability of 45.

FIG. 8A is the FMR of 0.65 mm magnetic laminate material formed by 4 layers of 3 μm MnZn-ferrite/100 μm FR4/3 μm MnZn-ferrite attached with a thin layer of 50 μm prepreg hot-pressed at 120° C.

FIG. 8B shows the permeability of 0.65 mm magnetic laminate material of FIG. 8A showing a permeability of 105.

FIG. 9A is the FMR of 0.65 mm magnetic laminate material formed by 4 layers of 3 μm MnZn-ferrite/100 μm FR4/3 μm MnZn-ferrite attached with a thin layer of epoxy glue hot-pressed at 120° C.

FIG. 9B shows the permeability of 0.65 mm magnetic laminate material of FIG. 9A showing a permeability of 30.

FIG. 10A is the FMR of 0.95 mm magnetic laminate material formed by 6 layers of 3 μm MnZn-ferrite/100 μm FR4/3 μm MnZn-ferrite attached with a thin layer of epoxy glue hot-pressed at 120° C.,

FIG. 10B shows the permeability of 0.95 mm magnetic laminate material of FIG. 10A, showing a permeability of 70.

FIG. 11A is the FMR of 1.3 mm magnetic laminate material formed by 8 layers of 3 μm MnZn-ferrite/100 μm FR4/3 μm MnZn-ferrite attached with a thin layer of epoxy glue hot-pressed at 120° C.

FIG. 11B shows the permeability of 1.3 mm magnetic laminates material of FIG. 11A, showing a permeability of 78.2.

FIG. 12A is the FMR of 1.5 mm magnetic laminate material formed 10 layers of 3 μm MnZn-ferrite/100 μm FR4/3 μm MnZn-ferrite attached with a thin layer of epoxy glue hot-pressed at 120° C.

FIG. 12B shows the permeability of 1.5 mm magnetic laminates material of FIG. 12A, showing a permeability of 103.

FIG. 13 is the real permeability of the 0.65 mm thick Ferrite PCB of FIG. 2 during a period of two months, showing a stable high permeability over time.

FIG. 14A is an optical image of the T-shaped matching network with a 5-turn solenoid magneto-dielectric antenna based on a blank PCB with a size of 25.4 mm×12.7 mm×1.3 mm.

FIG. 14B is an optical image of the T-shaped matching network with a 5-turn solenoid magneto-dielectric antenna based on a Ferrite PCB with the same size of 25.4 mm×12.7 mm×1.3 mm.

FIG. 15A is the S11 measurement of the 5-loop solenoid antennas of FIG. 14A and FIG. 14B at 30˜300 MHz.

FIG. 15B is the S21 measurement of the 5-loop solenoid antennas of FIG. 14A and FIG. 14B at 30˜300 MHz for comparison.

FIG. 16A is an image of two power inductors with the core size of 5 mm by 12 mm with or without the 20 layers MnZn Ferrite films on Kapton.

FIG. 16B shows the inductances of the power inductors in FIG. 16A.

FIG. 16C shows the quality factors of the inductors in FIG. 16A.

FIG. 17A to C show two examples of ferrite PCBs of different thicknesses manufactured by spin spray methods of Winchester Technology, LLC in accordance with their methods.

FIG. 18A shows result of a MAXWELL3D simulated via-based ferrite inductor's inductance (L) over frequency.

FIG. 18B shows result of MAXWELL3D simulated via-based ferrite inductor's quality factor (Q) over frequency.

FIGS. 19A-19C show results of HFSS simulated via-based inductors' respective inductance (L) and Quality Factor (Q) over frequency in a 300 μm-thick PCB interposer.

FIGS. 20A-20C show results respective inductance (L) and Quality Factor (Q) of ferrite via-based inductors manufactured by spin-spraying 3 μm Mn—Zn ferrite into via holes of a 1-mm thick PCB.

FIG. 21A is an example uniform ferrite coated PCB with via-holes.

FIG. 21B is a sectional view of the coated PCB with via-holes of FIG. 21A.

FIGS. 22A-22E show an example process flow and structure of the microfabrication of an I-shaped via-based ferrite inductor.

FIGS. 23A-23C show an example process flow and structure of the microfabrication of a U-shaped via-based ferrite inductor.

FIGS. 24A-24C show an example process flow and structure of the microfabrication of hexagonal array vias-based ferrite inductor.

FIGS. 25-26 show examples of schematic designs for vias with various directions with either through slits or semi-through holes on a whole wafer substate including PCB, glass, Si, SiC, GaN, GaAs, AlN, BN or more.

FIGS. 27A-27B illustrate a front and a sectional view of a via-based inductor without ferrite coating or ferrite loops.

FIGS. 28A-28B illustrate a front and a sectional view of a via-based inductor with ferrite coating but no ferrite loop.

FIGS. 29A-29B illustrate a front and a sectional view of a via-based inductor with ferrite coating and one ferrite loop.

FIGS. 30A-30B illustrate a front and a sectional view of a via-based inductor with ferrite coating and two ferrite loops.

FIGS. 31A-31F illustrate another example of a beehive like ferrite-via substrate hybrid structure and the fabrication process thereof.

### DETAILED DESCRIPTION OF THE INVENTION

Reference will now be made in detail to embodiments of the invention. Wherever possible, the same or similar reference numerals are used in the drawings and the description to refer to the same or like parts or steps. The drawings are in simplified form and are not of a precise scale. The word ‘couple’ and similar terms do not necessarily denote direct and immediate connections or include connections through intermediate elements or devices. For convenience and clarity only, directional (up/down, etc.) terms may be used with respect to the drawings. These and similar directional terms should not be construed to limit the scope in any manner. It will also be understood that other embodiments may be utilized without departing from the scope of the present invention, and that the detailed description is not to be taken in a limiting sense, and that elements may be differently positioned, or otherwise noted as in the appended claims without requirements of the written description being required thereto.

The terms “first,” “second,” “third,” “fourth,” and the like in the description and the claims, if any, may be used for distinguishing between similar elements and not necessarily for describing a particular sequential or chronological order. It is to be understood that the terms so used are interchangeable. Furthermore, the terms “comprise,” “include,” “have,” and any variations thereof, are intended to cover non-exclusive inclusions, such that a process, method, article, apparatus, or composition that comprises a list of elements is not necessarily limited to those elements but may include other elements not expressly listed or inherent to such process, method, article, apparatus, or composition.

The present invention may be described herein in terms of functional block components and various processing steps. It should be appreciated that such functional blocks may be realized by any number of hardware and/or software components configured to perform the specified functions. For example, the present invention may employ various integrated circuit components, e.g., memory elements, processing elements, logic elements, look-up tables, and the like, which may carry out a variety of functions under the control of one or more microprocessors or other control devices.

It should be appreciated that the particular implementations shown and described herein are illustrative of the invention and its best mode and are not intended to otherwise limit the scope of the present invention in any way. Furthermore, the connecting lines shown in the various figures contained herein are intended to represent exemplary functional relationships and/or physical couplings between the various elements. It should be noted that many alternative or additional functional relationships or physical connections may be present in a practical incentive system implemented in accordance with the invention.

The term “substrate” refers to the “substrate” term in electrical or electronic engineering field, a wafer is a common example; in general, substrate refers to a solid (usually planar) substance onto which a layer of another substance is applied, and to which that second substance adheres, this substance serves as the foundation upon which electronic devices such as transistors, diodes, and especially integrated circuits (ICs) are deposited.

The term “FR-4 (or FR4)” is a NEMA grade designation for glass-reinforced epoxy laminate material. FR-4 is a composite material composed of woven fiberglass cloth with an epoxy resin binder that is flame resistant.

The term “permeability” in this application refers to magnetic permeability. Magnetic permeability is generally measured by a permeameter, such as the RFMag26 commercialized by the inventors. Permeability is typically represented by the (italicized) Greek letter μ. It is the ratio of the magnetic induction B to the magnetizing field H as a function of the field H in a material. In SI units, permeability is measured in Henries per meter (H/m), or equivalently in newtons per ampere squared (N/A²). The permeability constant μ₀, also known as the magnetic constant or the permeability of free space, is the proportionality between magnetic induction and magnetizing force when forming a magnetic field in a classical vacuum. The magnetizing field H is generated around electric currents and displacement currents, and also emanates from the poles of magnets. The SI units of H are amperes/meter. The magnetic flux density B which acts back on the electrical domain, by curving the motion of charges and causing electromagnetic induction. The SI units of B are volt-seconds/square meter (teslas). Relative permeability, denoted by the symbol μr is the ratio of the permeability of a specific medium to the permeability of free space μ₀ where μ₀≈4π×10⁻⁷ H/m is the magnetic permeability of free space. In this application, permeability and relative permeability are used interchangeably. When an AC magnetic field of angular frequency ω is applied to ferrite material, the associated flux density is usually delayed by the phase angle om due to losses, thus, magnetic permeability is a complex property μ(ω)=real permeability-imaginary permeability, where real part represents the material's storage capacity of magnetic field whereas imaginary part represents losses and power dissipation. The real part can be related to inductance and the imaginary part to resistance.

The term “PCB” or “printed circuit board” refers to a flat sheet of insulating substrate material and a layer of copper foil, laminated to the substrate; chemical etching divides the copper layer into separate conducting lines into tracks or circuit traces, pads for connections, vias to pass connections between layers of copper. In multi-layer boards, the layers of material are laminated together in an alternating sandwich: copper, substrate, copper, substrate, copper, etc, each plane of copper is etched, and any internal vias are through, before the layers are laminated together. FR-4 glass epoxy is the most common insulating substrate. Another substrate material is cotton paper impregnated with phenolic resin, often tan or brown. Laminates are manufactured by curing under pressure and temperature layers of cloth or paper with thermoset resin to form an integral final piece of uniform thickness. The size can be up to 4 by 8 feet (1.2 by 2.4 m) in width and length. Different dielectrics are used as substrate, include polytetrafluoroethylene (Teflon), FR-4, FR-1, CEM-1 or CEM-3. Well known pre-preg materials used in the PCB industry are FR-2 (phenolic cotton paper), FR-3 (cotton paper and epoxy), FR-4 (woven glass and epoxy), FR-5 (woven glass and epoxy), FR-6 (matte glass and polyester), G-10 (woven glass and epoxy), CEM-1 (cotton paper and epoxy), CEM-2 (cotton paper and epoxy), CEM-3 (non-woven glass and epoxy), CEM-4 (woven glass and epoxy), CEM-5 (woven glass and polyester).

The term “inductor” refers to an electronic component designed to add inductance to a circuit. Inductance is defined as the ratio of the induced voltage to the rate of change of current causing it. It is a proportionality constant that depends on the geometry of circuit conductors (e.g., cross-section area and length) and the magnetic permeability of the conductor and nearby materials. It is customary to use the symbol L for inductance. In the SI system, the unit of inductance is the henry (H), which is the amount of inductance that causes a voltage of one volt, when the current is changing at a rate of one ampere per second. In the context of inductors, the Q factor represents the efficiency of energy storage and release in the magnetic field, as well as the energy loss in the form of heat due to the coil's resistance. The Q factor of an inductor is a dimensionless parameter as the ratio of its inductive reactance (XL) to its series resistance (R) at a specific frequency. A high Q value indicates low energy loss and high performance in applications like filters and oscillators.

The term “via-based inductor, or simply via inductor”, refers to a type of inductor that uses a magnetic, such as ferrite, core and a via hole to create a magnetic path. A via hole is a small opening in a printed circuit board (PCB) that connects different layers of the board. A via-based ferrite inductor can be used to filter out high-frequency noise and improve the performance of electronic circuits.

The term “transformer” in this application refers to the ordinary meaning in electrical engineering, that is, a passive component that transfers electrical energy from one electrical circuit to another circuit, or multiple circuits. A varying current in any coil of the transformer produces a varying magnetic flux in the transformer's core, which induces a varying electromotive force (EMF) across any other coils wound around the same core. The examples given are based on inductors, but the designs and methods are also suitable for manufacturing ferrite transformers and other similar devices.

Commercially available PCBs are mostly not magnetic, but only dielectric with a dielectric constant in the range of 2˜13. Because ferrite deposition requires greater than 700° C. processing temperature in order to form high crystalline quality ferrite, it has been almost impossible for electronic engineers to manufacture magnetic PCBs with traditional methods. Since magnetic PCBs can lead to more compact and more power-efficient antennas, inductors, and transformers, etc., which will, in turn, allow for the manufacturing of electronics with much smaller sizes, less weight, and less power consumption, many efforts have been made in finding a way to deposit ferrite material on PCBs, including the recent report by Rogers Corporation who generated a type of magnetic PCBs by packing magnetic powders into polymers. However, this type of magnetic PCBs only demonstrated a magnetic relative permeability of 5, also with large loss tangents at 400˜500 MHz. In addition, Rogers Corporation's method works with limited PCB sizes, but is heavy and hard to machine with significant loss tangents that limit their applications.

This application discloses a new way of manufacturing magnetic PCBs by spin spray deposition of high-quality low-cost thick ferrite films onto thin PCBs, such as FR4, and using prepreg or epoxy and hot-pressing for forming thick PCBs. A ferrite film is formed on a substrate during aqueous ferrite solution deposition. Substrate spinning will improve the thickness uniformity of the ferrite layer formed on the substrate and rinse excess oxide particles away from the substrate surface. The formation process is performed at temperatures less than about 100° C., which is particularly advantageous given the temperature sensibility of PCBs.

Embodiments of the invention may be used to deposit ferrite films on various substrate materials. Preferably deposition is at low temperatures, such as about 100° C. or less. The process depends on the controlled atomization of an aqueous oxidizing solution and an aqueous ionic solution of metal cations sprayed sequentially on the surface of a rotating, heated substrate.

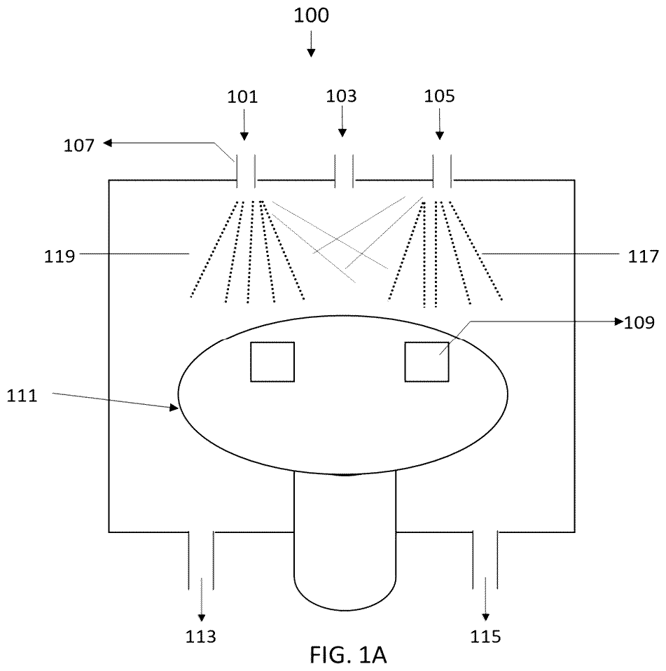

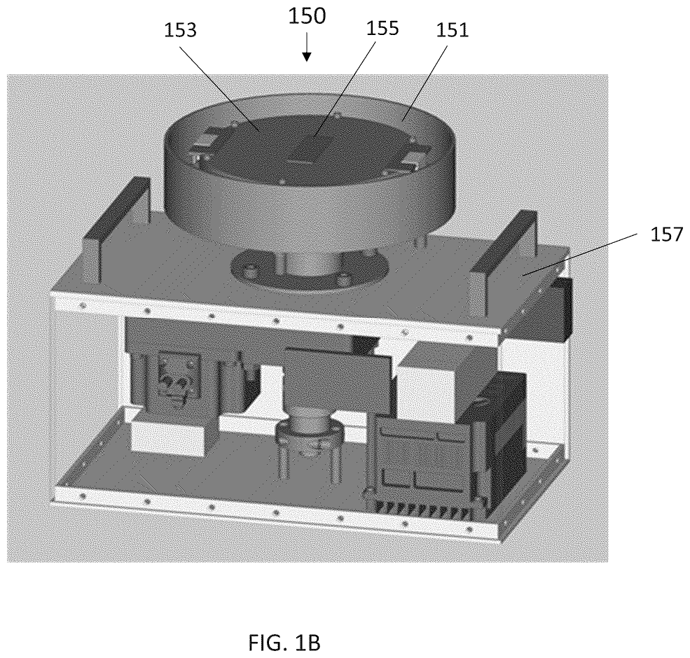

In reference to FIG. 1A spin spray system 100 is a closed reaction chamber like system including at least two nebulizers. Nebulizer 101 and nebulizer 105 are for spraying ionic reaction solutions 119 and for spraying oxidation solutions 117, 103 is for injecting N₂ gas into the chamber. Enclosed inside the reaction chamber is the substrate spinning table system 111 for supporting, heating, and spinning substrate piece 109. Spray mist fogs 119 and 117 are designed to cover the entire supporting table 111, and in the alternative, multiple nebulizers may be installed to render uniform depositions, and multiple substrate pieces may be placed on the substrate spinning table at the same time. Unreacted excessive solutions sprayed upon the substrate(s) are spun off the substrates and exit the table through drain outlet 113 and 115. Support Table 111 is configured with substrate supporting top panel 110 with a temperature-controlling heating facility, which is mounted on a rotation spindle 112 with a motor that rotates supporting panel 110.

An example spinning table machine system 150 is shown in FIG. 1B. Preferably, the substrate supporting panel 153 is placed inside a round cylinder chamber or container structure 151 which would collect spun off solutions from panel 153. Preferably, substrate supporting panel 153 is a circular disc of 24″ diameter. Other shapes may be adopted as well. External cylinder chamber 151 is fixedly mounted to support column 160 that remains motionless while substrate supporting panel 153 is mounted to a rotation spindle contained inside column 160. A heating facility is coupled with panel 153 so that panel 153 would be uniformly heated. Panel 153 may be made of metal or other heat conductive material, while cylinder chamber structure 151 may be made of heat-insulating material. Alternatively, cylinder chamber 151 may be made of other shapes or forms to function as an excessive solution drain and sealed reaction chamber. When in use, substrate 155 is placed face up on supporting panel 153 to receive a sprayed mist of ionic solution and oxidation solution, while the supporting panel 153 is heated to a specified reaction temperature and rotates at a specified speed. Preferably, the rotation speed is around 90 rpm and the temperature is heated up to 100° C., or anywhere between room temperature and 300° C. The spray flow rates of the reactants and the oxidants may be configured between 1 mL/min and 1000 mL/min.

### Example 1: Use of the Spin-Spray Ferrite Deposition System

A six-liter oxidizing solution containing 0.84 g NaNO₂ and 69 g CH₃COONa is prepared and held in a container. Similarly, a six-liter cation ferrite solution containing FeCl₂ (9.21 g), ZnCl₂·6H₂O (0.246 g) and MnCl₂·6H₂O (0.867 g) is also prepared and held in a container. Bubbled nitrogen may be used in both containers to prevent premature oxidation of the cations and NaNO₂. These solutions were respectively flown through a 0.125″ diameter polypropylene tube to the spray nozzles 101 and 105.

To begin a deposition run, FR4 substrates were placed on the spin table with a spindle by using carbon tape. After the rpm of the spindle was set, the rotation was initiated. Preferably the rotational speeds were operated in the range of about 40 rpm to about 300 rpm. The substrate surface is then heated to a specified temperature, and it rotates on the spindle, and it is exposed to alternating sprays of oxidizer and cation solutions. Spacing between nozzles and the distance between the bottom of the nozzle and the substrate surface are part of the testing parameters. Preferably, the nozzles are placed directly over substrates, and the distance between nozzles and the surface of substrates is preferably in the range of about 1 inch to about 5 inches. Typically, the deposition time for an approximately 3 μm thick ferrite film at 90 rpm rotation speed is about 180 minutes.

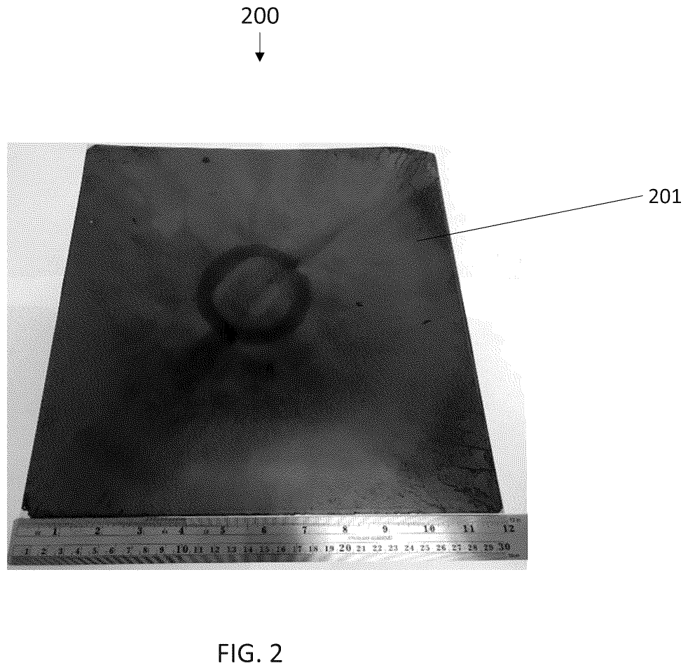

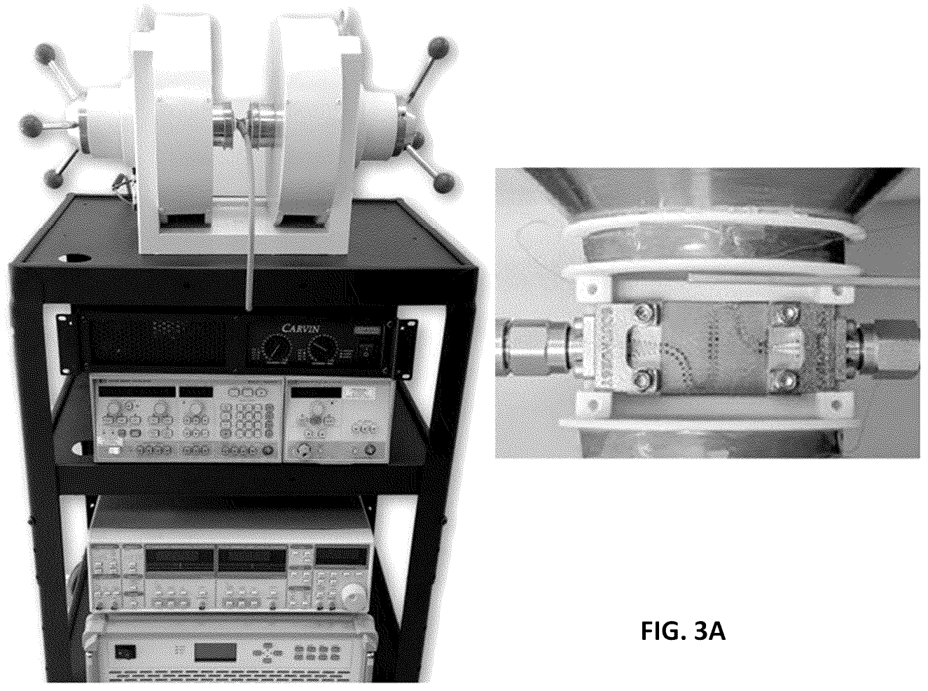

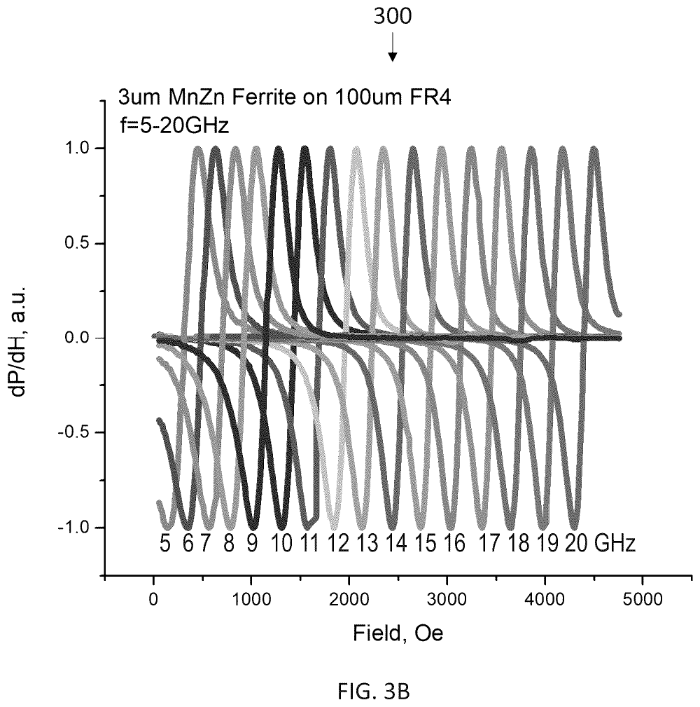

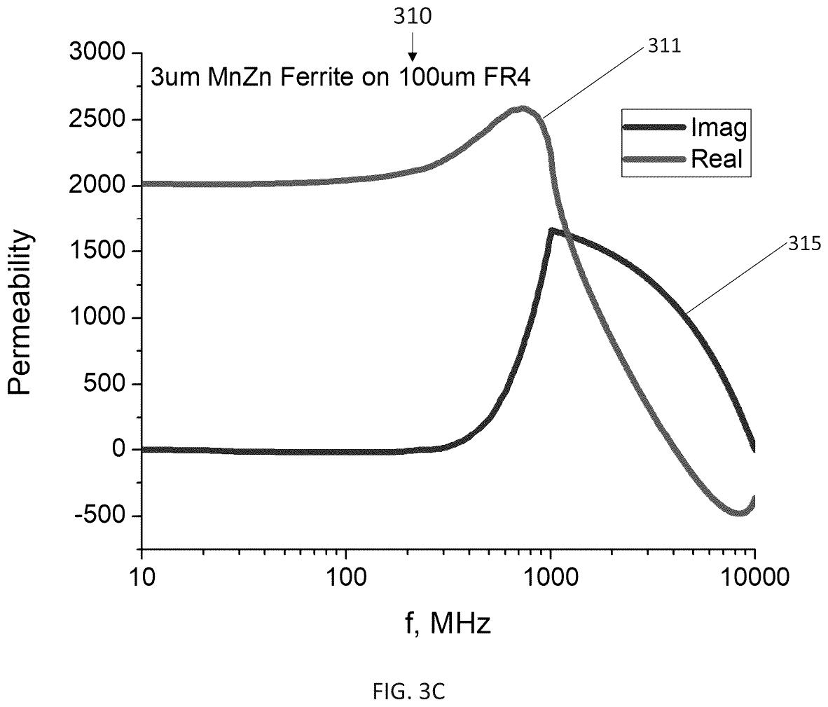

Typically, a higher rpm yields better quality films, for instance, it may increase the smoothness of the formed ferrite film. After metal-ferrite film formation, the substrate panel is covered with a blackish-gray layer of ferrite material. FIG. 2 shows the photo image of an example 3 μm MnZn Ferrite coated on 100 μm thick 12 inches by 12 inches FR4 substrate. The white or transparent uncoated FR4 is now in a blackish-gray color. The dark spots may be due to thicker deposition of the MnZn Ferrite. This deposited 3 μm MnZn Ferrite shows a high-level saturation magnetization that was greater than 0.8 T and a high permeability that was larger than 2000 as shown in FIG. 3B. The result was measured by instrument 302 in FIG. 3A.

This spin spray methods are capable of depositing MnxZn(1-x)-ferrite, where x is the ratio between Mn and Zn, films with an ultra-high relative permeability if different amount of MnCl₂ and ZnCl₂ are used in the cation ferrite solution. For example, a relative permeability of greater than 2000 and high saturation magnetic flux density Bs=0.85 Tesla may be obtained at 50/50 ratio of Mn_{0.5}Zn_{0.5}-ferrite composition. The spin spray reaction solutions may be composed of a chemical formula of FeCl₂ and MCl₂, where M is a metal ion like Zn, Co, Mn, Ni, or other metal ions, or the mixture of them, while the oxidizing solution is a mixture of a oxidant buffer, such as an acetate, CH₃COONa, CH₃COOK, CH₃COONH₄ and an oxidant, such as NaNO₂. The deposition reaction temperature preferably ranges between 70-120° C., and the speed of rotation of the supporting table at between 120-200 rpm for high quality films. The heating temperature, speed, and rotation may be adjusted for optimum reaction and deposition results.

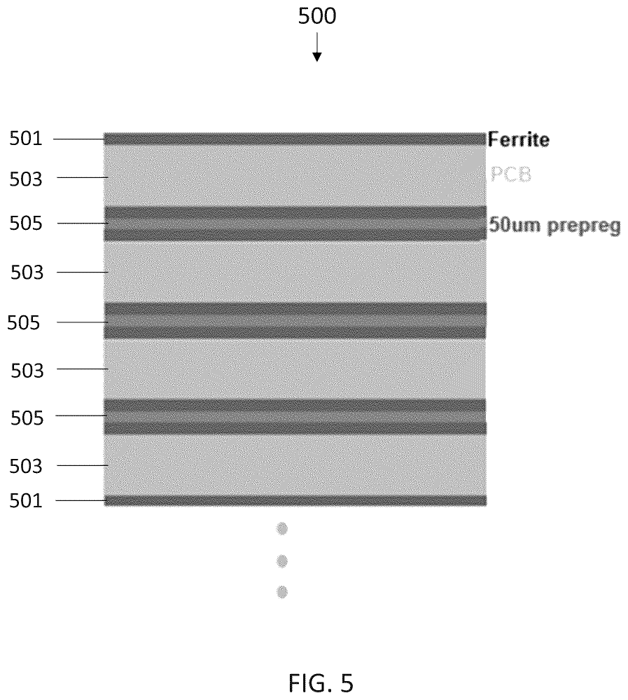

In reference to FIG. 5, a thicker film ferrite laminate 500 is fabricated by forming a layered assembly including two or more coated substrates, each coated substrate having a ferrite thin film, and heating the layered assembly to form the thick film ferrite laminate. In the diagram, a multilayer layered ferrite laminate structure 500 schematically comprises of a top layer of ferrite 501, middle layer PCB substrate 503, bottom layer of 501 which is glued by 50 μm of prepreg to another layer comprising ferrite coating 501, middle layer PCB substrate 503, bottom layer 501. This a four layered assembly may be formed by stacking two or more coated ferrite substrates, one on top of another as shown in FIG. 5, 503 represents a substrate and 501 represents a ferrite coat while 505 represents a thermos plastic resin or prepreg glue.

Alternatively coated substrates may be first formed by depositing ferrite on a larger substrate and cutting the larger coated substrate into several smaller ferrite coated pieces and stacking the smaller pieces together. A large substrate may be, for example, 12 inch by 12 inch as shown in FIG. 2. In other cases, layers of ferrite coated substrates may be formed individually. The ferrite coated substrates used to form a layered laminate assembly may have substantially uniform dimensions, or they may not be the same. The surface areas, shapes and thicknesses of the substrates can vary and can be stacked together. In one example, a circular substrate that has a diameter between 1 inch and 24 inches may be used. In another example, a substrate is square with a size of 1 ft by 1 ft. The thickness of the coated ferrite may vary in a range between 0.1 μm and 10 μm.

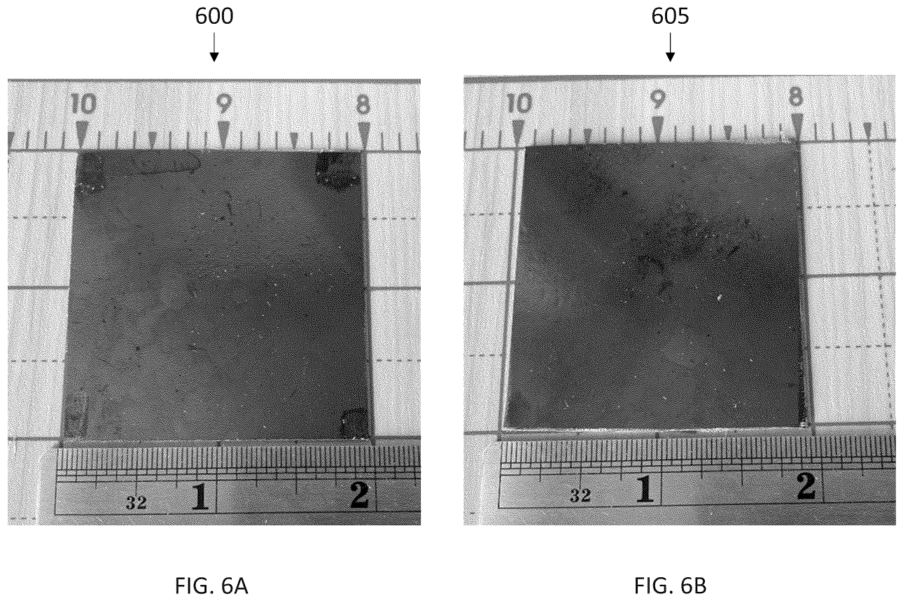

In some cases, the ferrite layer of a coated substrate may be first cleaned before they are used to form an assembly. The number of coated layers can vary, for example, at least 2 and less than 100, and they are stacked tightly together to form a layered assembly in a manner such that the ferrite layer of one coated substrate is in direct contact with an adhesion (such as prepreg) layer, which is in direct contact with another ferrite-coated or uncoated substrate. FIGS. 6A and 6B show two examples of a laminate with layers of 3 μm MnZn-ferrite/100 μm FR4/3 μm MnZn-ferrite attached with epoxy glue through hot-pressing.

Compressing the layered assembly may include positioning the layered assembly in a press and applying pressure to the layered assembly, forcing the coated substrates together. The pressure applied on the surface of the substrate may vary between 0.05 psi to 100 psi.

After a layer assembly is assembled in a press, the press is then heated to a temperature less than the transition temperature of one or more of the substrates in the layered assembly. The layered assembly may be heated at a ramp rate between 2° C./min and 30° C./min. In one example, a layered assembly is heated to a temperature between 120° C. to 250° C. After achieving the desired temperature, the layered assembly may continue to be heated for at least 30 mins or at least 1 hour. In some cases, the layered assembly is heated up to 3 hours or more. In certain cases, the layered assembly is heated for a specified desired time, the annealed layered assembly is left to cool down without disturbance.

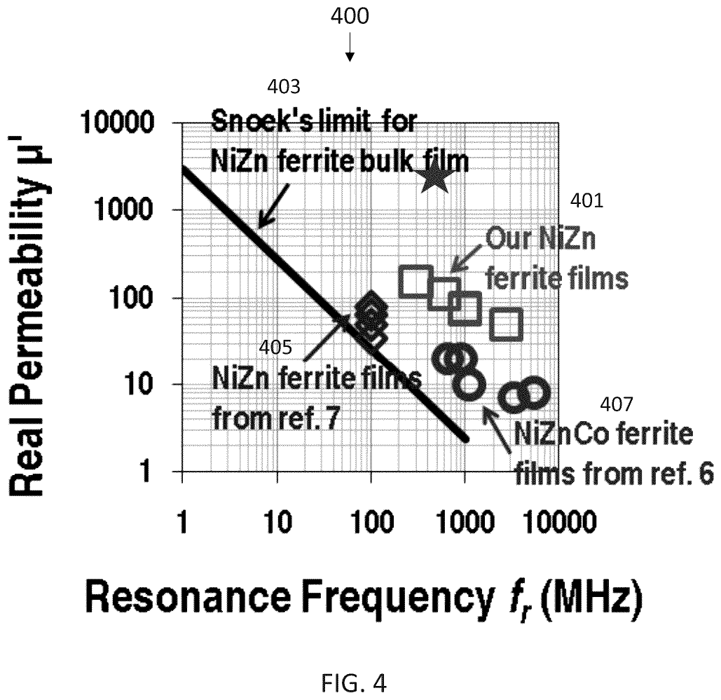

Advantages of spin-spray ferrite deposition and the magnetic PCBs assembly methods described herein include providing high permeability thick PCBs (0.5˜2 mm thick PCBs) with multilayered ferrite films, generating thick high permeability PCBs with a relative permeability μᵣ>100 at >300 MHz. FIG. 4 shows graph 400 of real permeability vs. resonance frequency. This graph compares the measured real permeability data of the spin-spray ferrite coated magnetic PCB in this application with other integrated RF thick magnetic ferrite films on PCB and Si substrates by published methods. 409 is the data point of the spin-spray MnZn ferrite coated PCB shown in FIG. 2, 401 refers to the data points of spin-spray NiZn ferrite filmed PCBs while 403 refers to Snoek's limit for NiZn ferrite bulk film, 405 refers to the data points of NiZn ferrite films of a publication and 407 refers to NiZnCo ferrite films of another publication. It is quite obvious that currently, there are no other methods in the market that generate magnetic PCBs with as high permeability as those generated by the spin-spray deposition method described in this application. The magnetic PCB applications may include inductors, antennas, and magnetic sensors. Advantages of the thin film ferrite laminates formed as described herein also include low cost, large-scale in size, and high permeability.

### Example 2: Ferromagnetic Resonance (FMR) Spectroscopy Measurement

FMR is the coupling between an electromagnetic wave and the magnetization of a medium through which the electromagnetic wave passes. This coupling induces a significant loss of power of the wave. The power is absorbed by the precessing magnetization of the material and lost as heat. For this coupling to occur, the frequency of the incident wave must be equal to the precession frequency of the magnetization (Larmor frequency) and the polarization of the wave must match the orientation of the magnetization.

The Ferromagnetic Resonance (FMR) Spectroscopy is a key technique used to measure the ferromagnetic resonance (FMR) line width for magnetic thin film samples. The typical working frequency of FMR system is 1 GHz to 10 GHz or higher. FIG. 3A schematically shows an inventor-made RFMag26 FMR spectrometer system. The non-resonant co-planar waveguide (CPW) can help the system overcome bandwidth restrictions for broadband operation. During the measurement, electromagnetic is controlled through software and the applied static magnetic field varies from 0 Oe to a maximum of 5˜10 kOe. Samples are mounted directly on to the CPW to make sure the microwave field is uniform over the sample area. The microwave frequency that is fed into the CPW will remain the same during each measurement cycle. Then the FMR absorption profile can be obtained through the field modulation method and a lock-in amplifier. The experimental FMR absorption versus magnetic field curve is usually symmetric. Linewidth can be determined through full width half maximum of the response.

FMR arises from the precessional motion of the (usually quite large) magnetization M of a ferromagnetic material in an external magnetic field H. The magnetic field exerts a torque on the sample magnetization, which causes the magnetic moments in the sample to precess. Ferromagnetic resonance (FMR) is a useful technique in the measurement of magnetic properties of a variety of magnetic media, from bulk ferromagnetic materials to nano-scale magnetic thin films. The precessional motion of a magnetization of a ferromagnetic material in relation to the applied external magnetic field is known as the FMR. In the actual process of resonance from a macroscopic point of view, the energy is absorbed from RF transverse magnetic field h_{rf}, which occurs when frequency is matched with precessional frequency. Microscopically, the applied field forges a Zeeman splitting in the energy levels, and the microwave excites magnetic dipole transitions between these split levels. The precession frequency depends on the orientation of the material and the magnitude of the applied magnetic field. It has the capability to measure all the most important parameters of the magnetic material, i.e., static properties: curie temperature, total magnetic moment, relaxation mechanism, elementary excitations; and dynamic properties. The dynamic properties of magnetic materials can be feasibly perplexed by FMR, by excitation of standing spin waves due to magnetic pinning.

FMR is usually measured at microwave frequencies (from a few GHz up to about 100 GHz) and the applied magnetic fields range from 0 up to a few T. Testing samples are placed in FMR spectrometer. The microwave power is supplied by klystron or other microwave generators. The power reflected from the device under test (DUT) containing the sample is measured by microwave detector. DUT can be microwave cavity, short-ended waveguide, CPW, or other microwave device.

In-plane FMR measurements were performed in an inventor-made RFMag26 FMR spectrometer (commercialized by Winchester Technologies, LLC) at room temperature. As shown in FIG. 3A for the FMR setup. The electromagnet produces the static in-plane magnetic field. A cylindrical cavity resonator is placed at the center of the electromagnet. The microwave unit connected with the microwave source by waveguide generates microwave (the RF magnetic field is normal to the bias magnetic field) and excites the magnetic sample.

FMR spectrum under a series of magnetic fields is converted into magnetic permeability μ (Greek mu), thus defined as μ=B/H. Magnetic flux density B is a measure of the actual magnetic field within a material considered as a concentration of magnetic field lines, or flux, per unit cross-sectional area, in an external magnetic field H.

### Example 3: Four and Eight Layered Ferrite Film-Coated PCB Assemblies

3 μm MnZn Ferrite thin film was deposited on a 100 μm thick FR4 substrate at 90° C.-120° C. by inventor's home-made 24 inch-diameter spin spray system as shown in FIG. 1B. After deposition, the ferrite was washed thoroughly with deionized water. The layered substrate was cut into 2″×2″ squares, and 4 of the 2″×2″ squares were stacked with a 50 μm prepreg and formed four layered assembly. The layered assembly was placed at a pressure of 0.65 psi, and at the same time the layer assembly was heated at 120° C. for 30 mins. After heating, the laminate was cooled down under a pressure of 0.65 psi. In FIG. 6A, 600 is an optical microscopy image of a 2″×2″×0.025″ four-layered laminate constructed of Mn—Zn ferrite deposited onto a FR4 substrate using a spin spray process.

Two four-layered ferrite filmed PCB assemblies were stacked 50 μm prepreg together and formed 8 layered ferrite filmed PCB assembly. In FIG. 6B, 605 is an optical microscopy image of a 2″×2″×0.05″ 8-layered laminate constructed of Mn—Zn ferrite deposited on to a FR4 substrate using a spin spray process.

### Example 4: NiZn Ferrite Thin Filmed TMM10i PCB

Using FeCl₂ (9.21 g), ZnCl₂·6H₂O (0.246 g) and NiCl₂·6H₂O (1.638 g) as ferrite solution and the process described in Example 1, 10 μm NiZn ferrite thin film was deposited on a TMM10i substrate at 90° C. by spin spray as described in Example 1. After deposition, the ferrite was washed thoroughly with deionized water.

### Example 5: Multi-Layered MnZn and NiZn Ferrite Filmed PCB Assemblies

The experiments in Examples 3 and 4 were repeated by busing Ni—Zn ferrite and Mn—Zn Ferrite. Briefly, varying number of layers of Ni—Zn ferrite filmed PCBs or Mn—Zn ferrite filmed PCBs were hot-pressured together with 50 μm pre-preg resulting with laminates thickness ranging from about 100 μm to about 10 mm. The laminated Ferrite Filmed PCB Assemblies were further measured for its real permeability.

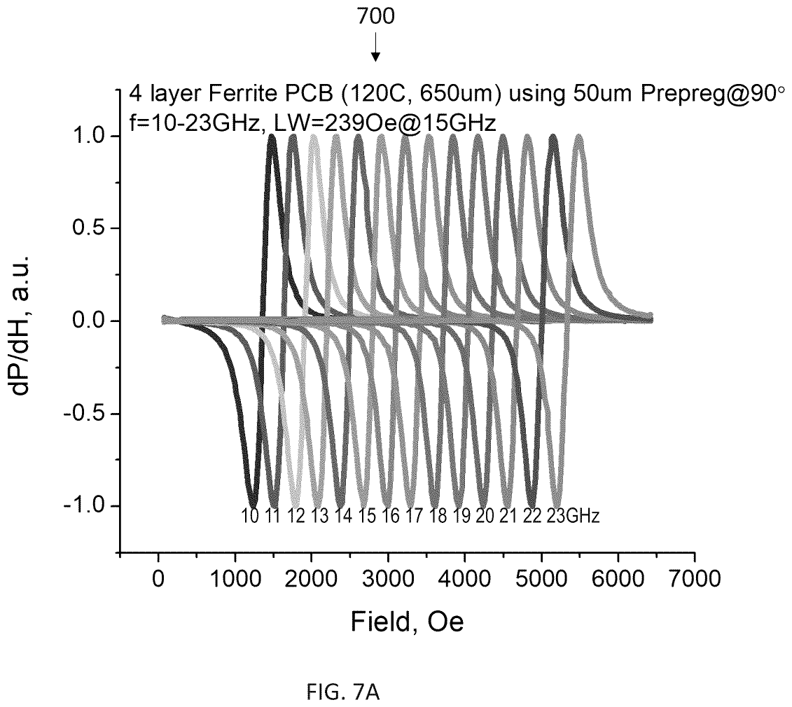

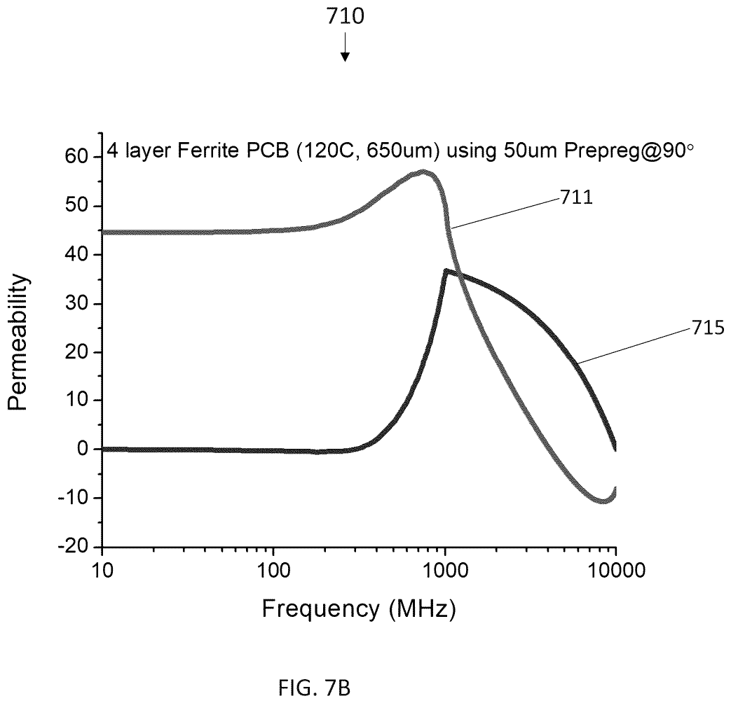

FIG. 7A shows the FMR spectrum 700 generated at external microwave frequency scan 10-23 GHz of the four layer PCB laminate of FIG. 6A of 0.65 mm magnetic laminate of 3 μm MnZn-ferrite/100 μm FR4/3 μm MnZn-ferrite (deposited at 120° C.) glued with a thin layer of 50 μm prepreg hot-pressed at 90° C. FIG. 7B shows the calculated real permeability and imaginary permeability graph 710 from the results of FIG. 7A. 711 is the real permeability, which shows a value of 45 in frequencies ranges of 10-800 MHz for this 4-layer 3 μm MnZn-ferrite/100 μm FR4/3 μm MnZn-ferrite laminate. 715 is the calculated corresponding imaginary permeability. The bigger the difference between the real permeability and the imaginary permeability, the less the loss of magnetism. As shown in FIG. 7B, at around 800 MHZ, the magnetism of this ferrite PCB laminate was completely lost.

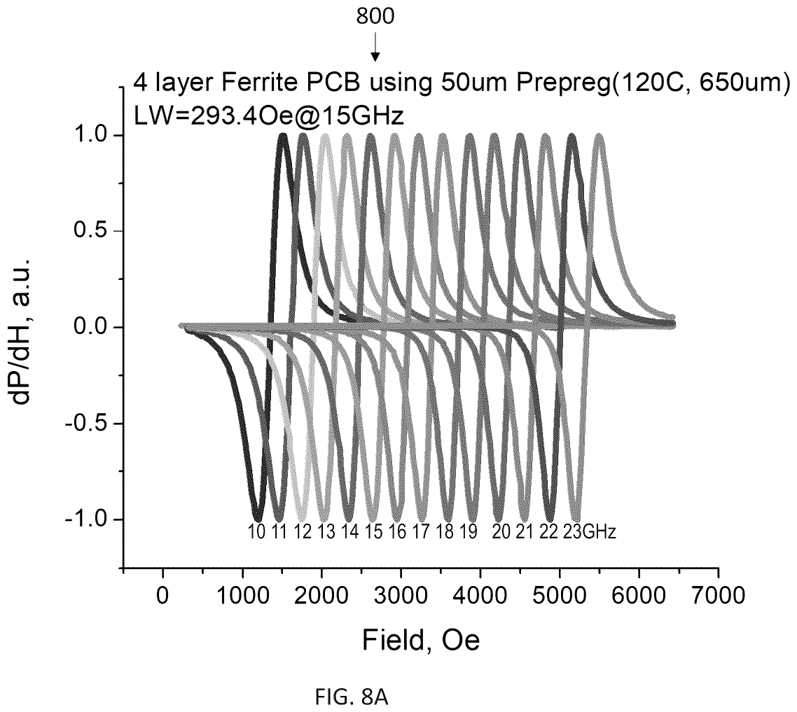

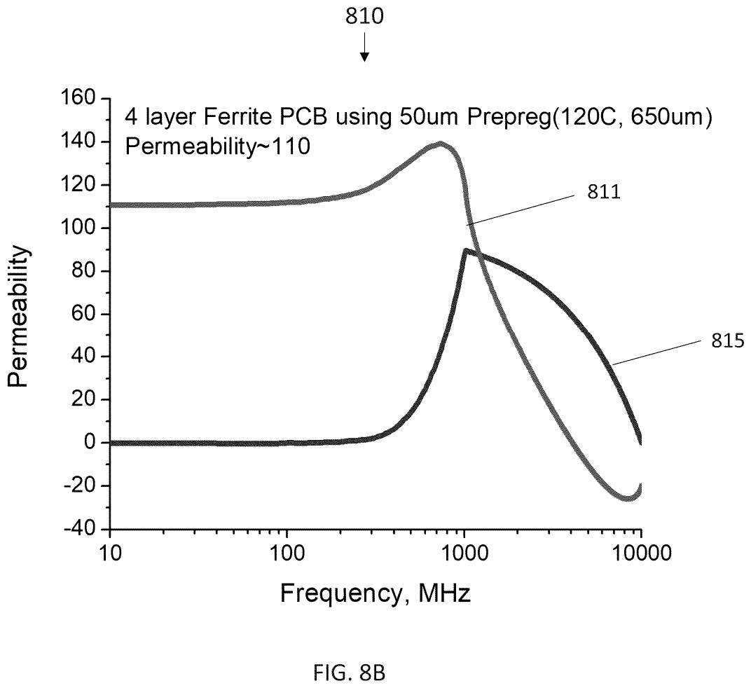

FIG. 8A shows the measurement of the FMRs of a 0.65 mm magnetic PCB laminate of 4 layers of 3 μm MnZn-ferrite/100 μm FR4/3 μm MnZn-ferrite attached with a thin layer of 50 μm prepreg hot-pressed at 120° C. FIG. 8B shows the calculated real permeability and imaginary permeability graph 810 from the results of FIG. 8A. 811 is the real permeability, which shows a value of 110 in frequencies ranges of 10-800 MHZ, a higher value than the one in FIG. 7B. As shown in FIG. 8B, at around 800 MHZ, the magnetism of this ferrite PCB laminate was completely lost.

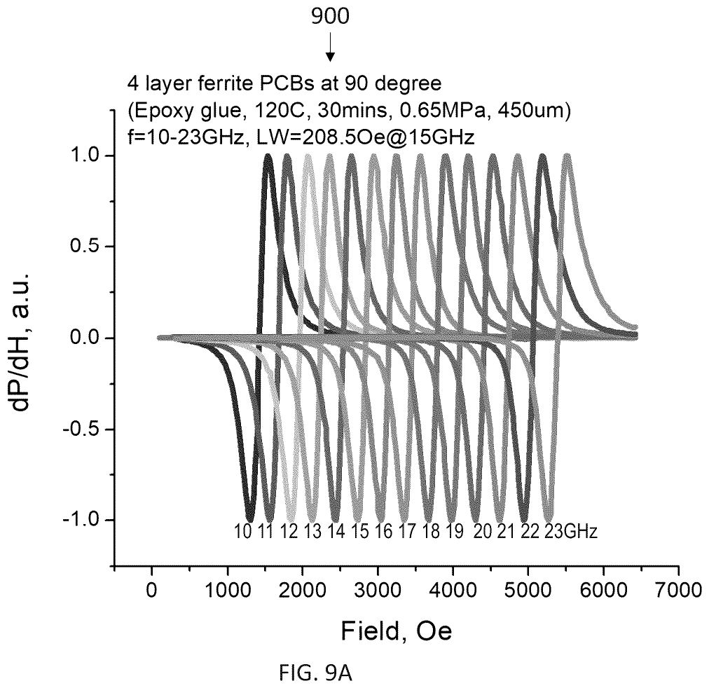

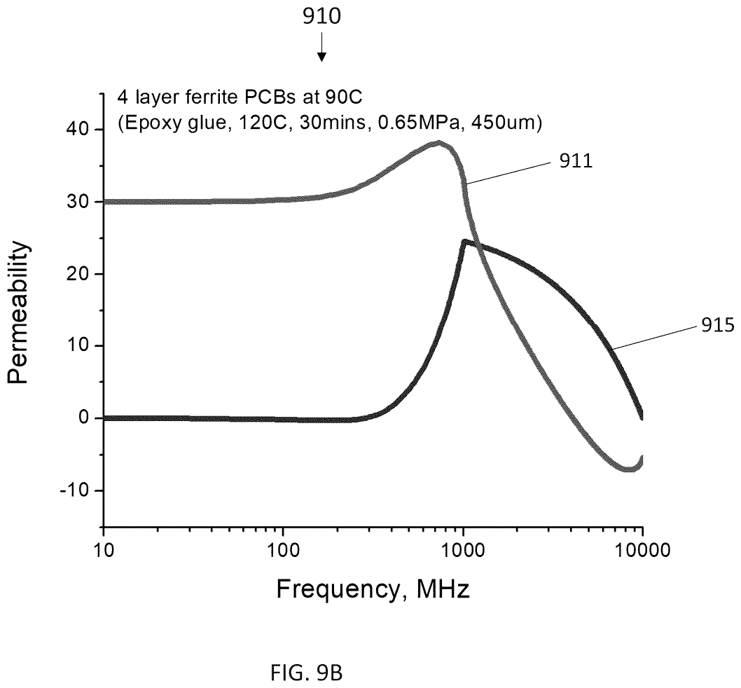

FIG. 9A shows the FMR of a 0.45 mm magnetic laminate formed by hot pressing 4 layers of 3 μm MnZn-ferrite/100 μm FR4/3 μm MnZn-ferrite (spin-spray deposited at 90° C.) attached with a thin layer of epoxy glue at 0.65 MPa at 120° C. for 30 minutes. FIG. 9B shows the calculated real permeability and imaginary permeability graph 910 from the results of FIG. 9A. 911 is the real permeability, which shows a value of 30 in frequencies ranges of 10-800 MHZ, a worse value than the one in FIG. 8B. As shown in FIG. 9B, at around 800 MHZ, the magnetism of this ferrite PCB laminate was completely lost.

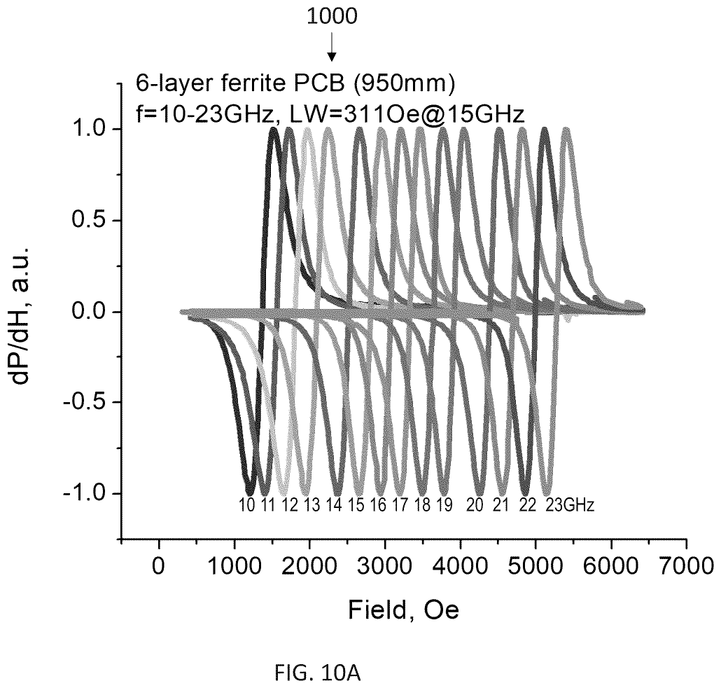

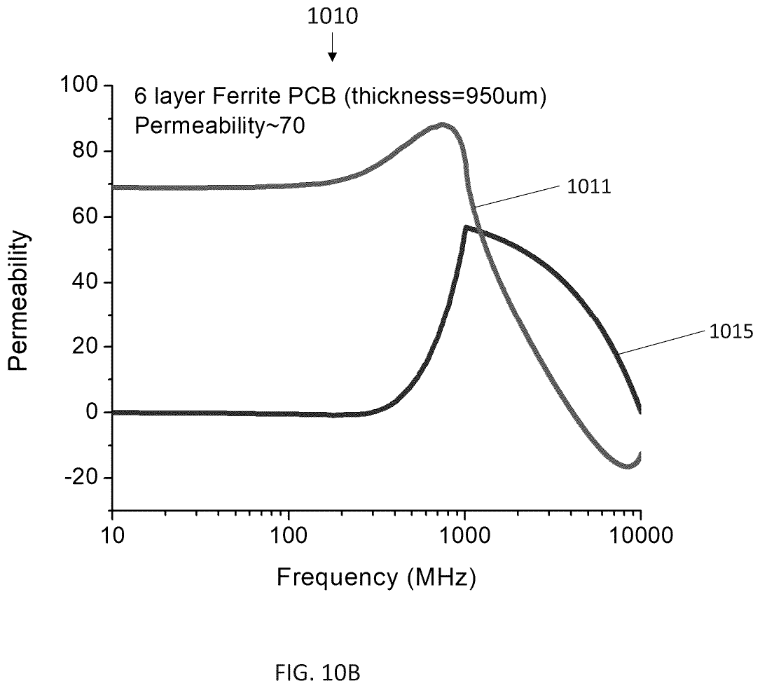

FIG. 10A shows the FMR of a 0.95 mm magnetic PCB laminate formed by a 6-layers of 3 μm MnZn-ferrite/100 μm FR4/3 μm MnZn-ferrite attached with a thin layer of 50 μm prepreg. FIG. 10B shows the calculated real permeability and imaginary permeability graph 1010 from the results of FIG. 10A. 1011 is the real permeability, which shows a value of 70 in frequencies ranges of 10-800 MHZ, a better value than the one in FIG. 9B. As shown in FIG. 10B, at around 800 MHZ, the magnetism of this ferrite PCB laminate was completely lost.

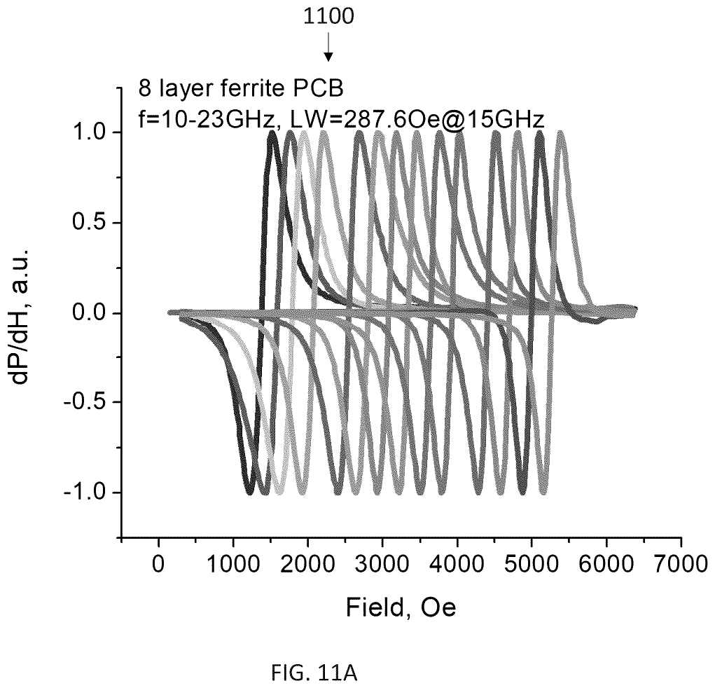

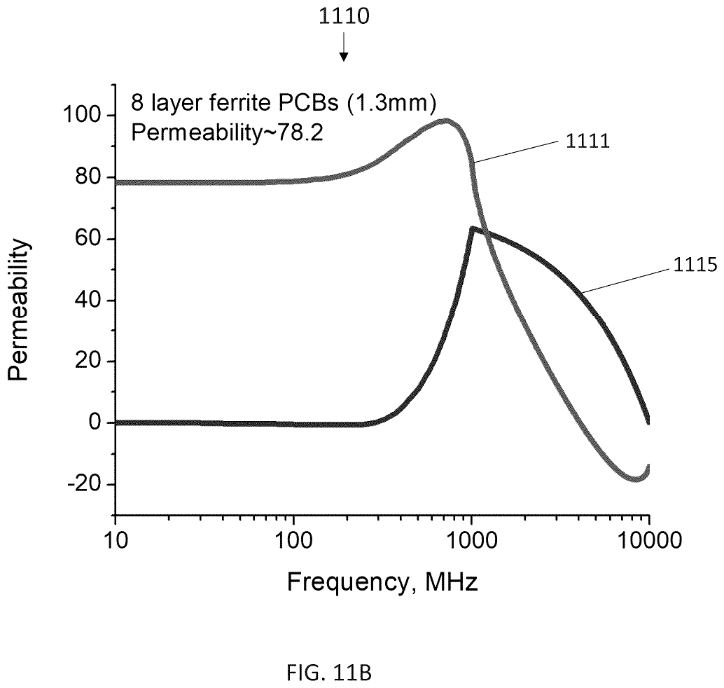

FIG. 11A shows the FMR of a 1.3 mm magnetic PCB laminate formed by 8 layers of 3 μm MnZn-ferrite/100 μm FR4/3 μm MnZn-ferrite attached with a thin layer of 50 μm prepreg. FIG. 11B shows the calculated real permeability and imaginary permeability graph 1110 from the results of FIG. 11A. 1111 is the real permeability, which shows a value of 78.2 in frequencies ranges of 10-800 MHZ, a better value than the one in FIG. 10B. As shown in FIG. 11B, at around 800 MHZ, the magnetism of this ferrite PCB laminate was completely lost.

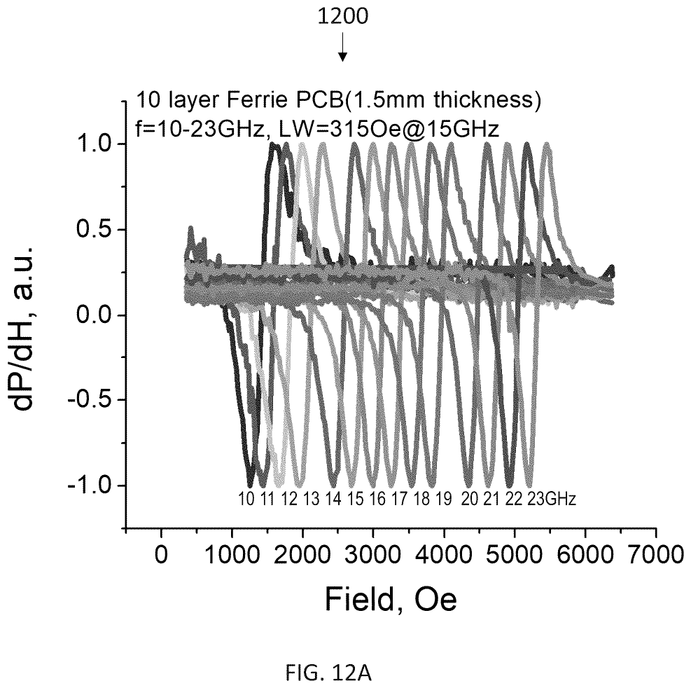

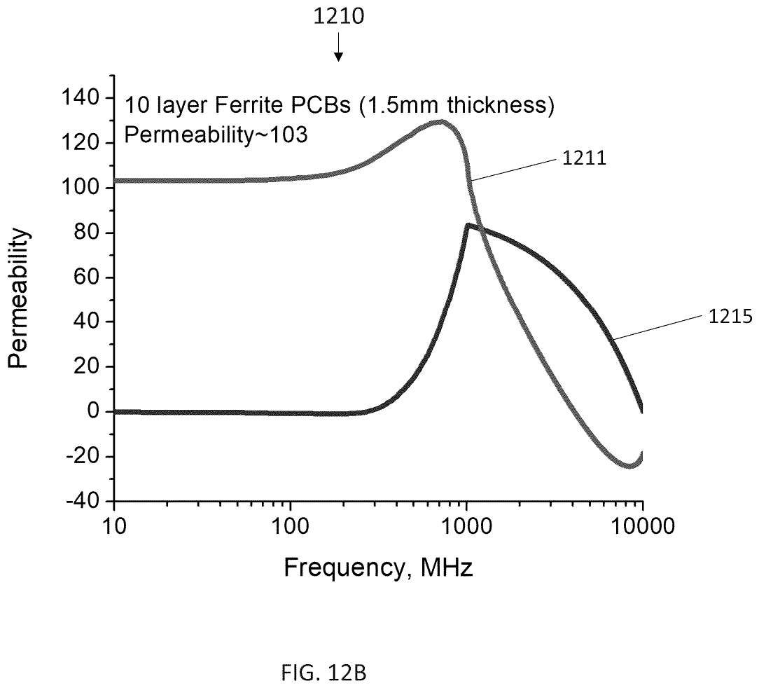

FIG. 12A shows the FMR a 1.5 mm magnetic PCB laminate formed by 10 layers of 3 μm MnZn-ferrite/100 μm FR4/3 μm MnZn-ferrite attached with a thin layer of 50 μm prepre. FIG. 12B shows the calculated real permeability and imaginary permeability graph 1110 from the results of FIG. 12A. 1211 is the real permeability, which shows a value of 103 in frequencies ranges of 10-800 MHZ, a better value than the one in FIG. 11B. As shown in FIG. 12B, at around 800 MHZ, the magnetism of this ferrite PCB laminate was completely lost.

The above measured data indicate that magnetic PCBs are functionally superior and stable in frequencies 10-800 MHz.

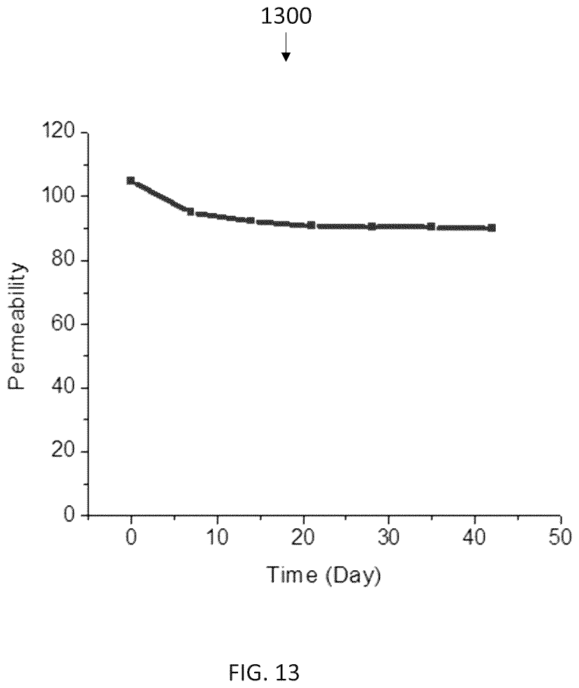

FIG. 13 shows the permeability measurement of the 0.65 mm thick Ferrite PCB laminate of FIG. 8A for two months, showing a stable high permeability for this period.

### Example 6: Antennas Using Ferrite Filmed PCB Assemblies

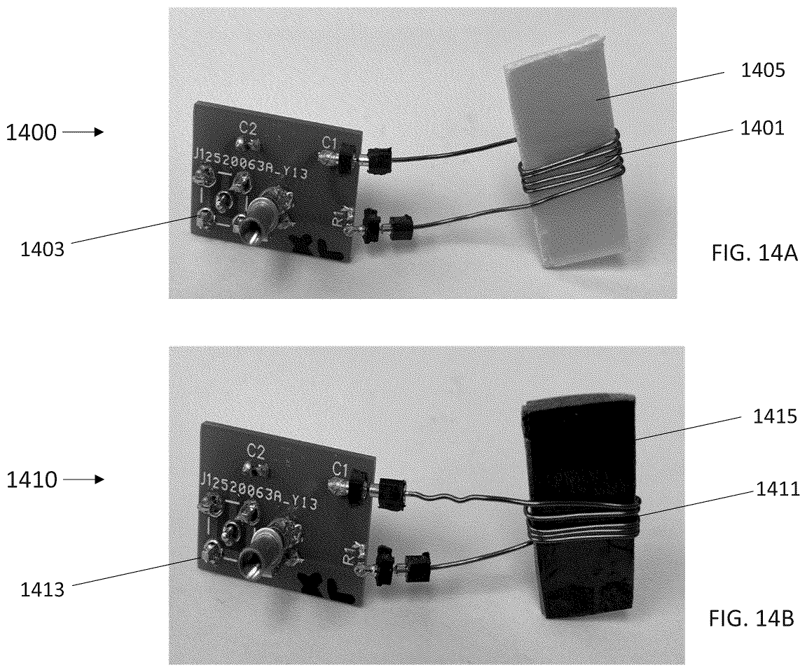

FIG. 14A shows a fabricated and soldered PCB 1403 of a T-shaped matching network 1400 with 5-turn solenoid magneto-dielectric antenna 1401 based on a blank 25.4 mm×12.7 mm×1.3 mm PCB 1405 (of light color). FIG. 14B shows a fabricated and soldered PCB 1413 of a T-shaped matching network 1410 with 5-turn solenoid magneto-dielectric antenna 1411 based on a ferrite PCB 1415 (of dark color due ferrite coating) with the same size of 25.4 mm×12.7 mm×1.3 mm. The magnetic PCB is from FIG. 12A and both magnetic and blank PCBs are of 1.5 mm thickness.

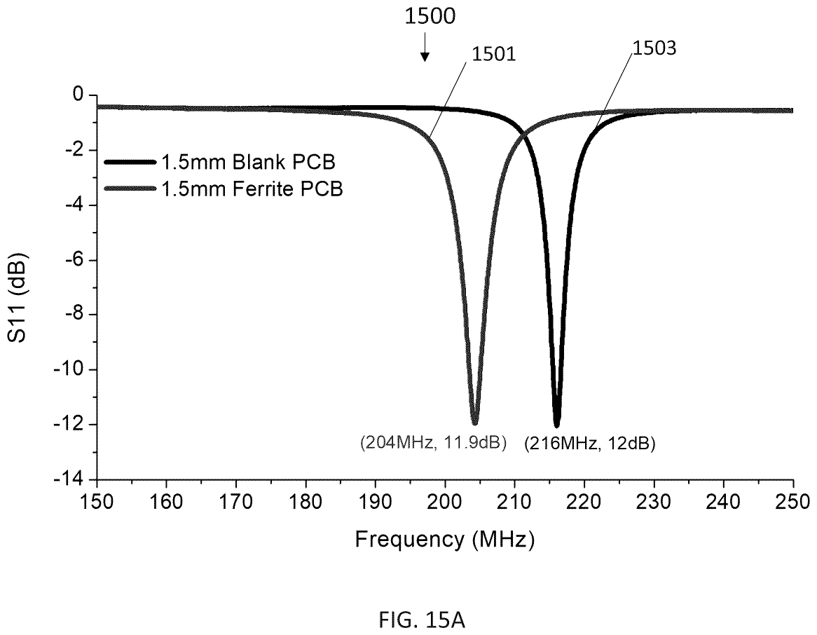

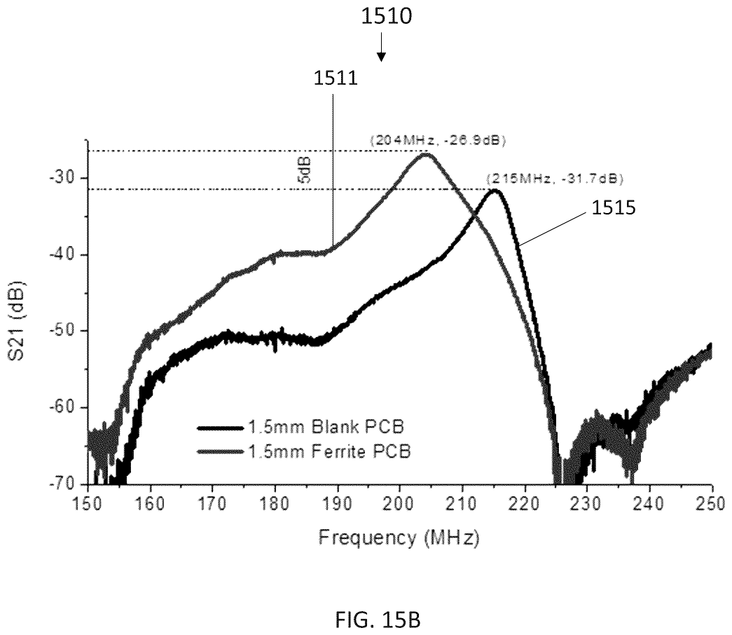

FIG. 15A shows the S11 comparison 1500 of the 5-loop solenoid antennas shown in FIG. 14A and FIG. 14B. These results show a return loss of the solenoid magneto-dielectric antenna based on magnetic PCBs with the dimension of 25.4 mm×12.7 mm×1.5 mm. In frequency range of 30˜300 MHz, matching networks were not tuned, and there is a resonance frequency shifts from 216 MHz (blank PCB, 1503) to 204 MHz (magnetic PCB, 1501). In reference to FIG. 15B, the S21 comparison 1510 is calculated. At the resonance frequency of 204 MHZ, the magnetic PCB antenna enhances the gain by 5 dB (plot 1511) compared to the antenna based on the blank PCB (plot 1515). Therefore, the present invention can design small-size antennas having improved antenna gains and bandwidths and various low resonance frequencies by using a high permeability magnetic PCB.

### Example 7: Inductors Using Ferrite Filmed PCB Assemblies

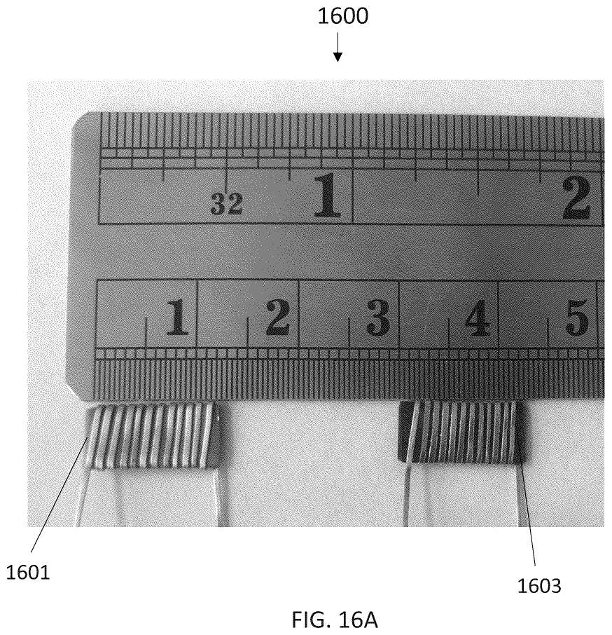

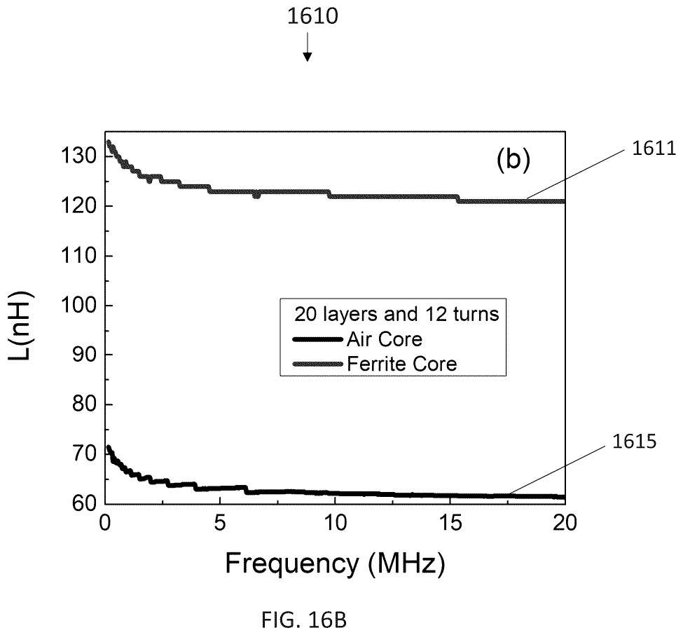

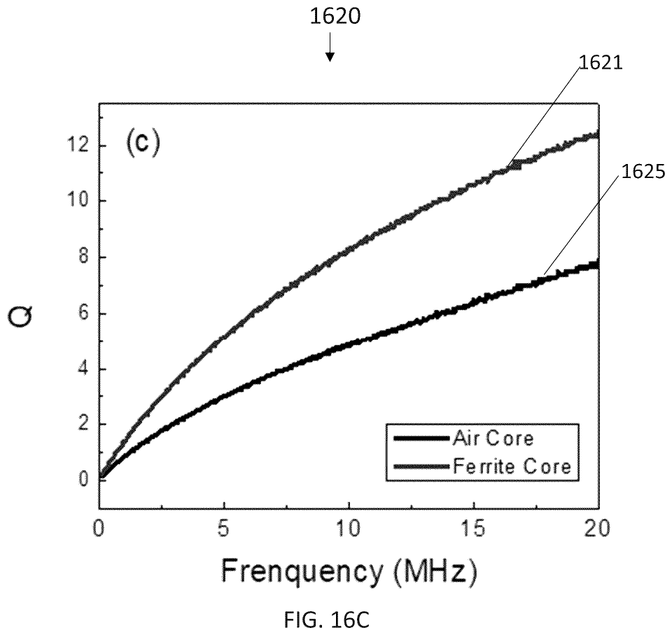

FIG. 16A shows the images of a power inductor 1603 based on 20 layers MnZn ferrite filmed Kapton PCBs (1603) with the core size of 5 mm by 12 mm and a power inductor 1601 with same sized un-coated Kapton PCBs. FIG. 16B shows the inductance comparison graph 1610 between the two inductors. FIG. 16C shows the quality factor comparison graph 1620 between the two inductors.

FIG. 16B shows a significantly higher inductance (plot 1611) in MnZn ferrite filmed Kapton PCB inductor, exhibiting nearly constant inductance, compared to the uncoated Kapton PCBs inductor (plot 1615). FIG. 16C shows a significantly higher quality factor 1621 at MHz frequencies over their air core counterparts (plot 1625), exhibiting about 96% enhancement between 150 kHz˜20 MHz relative to the air core inductor.

### Example 8: Via-Based Inductors and Transformers

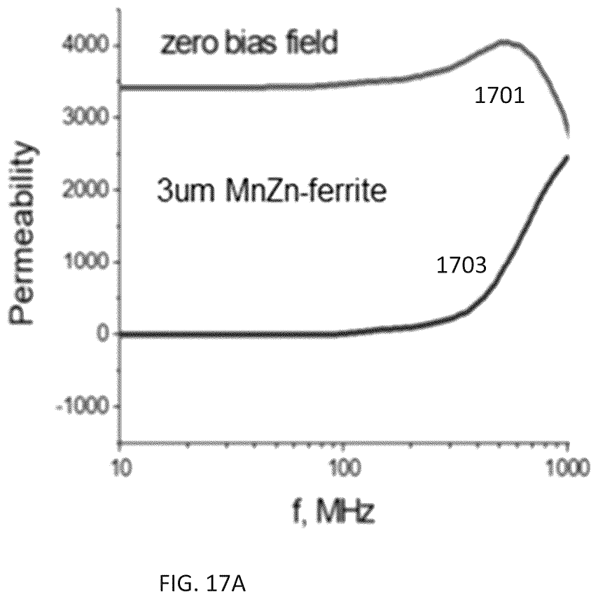

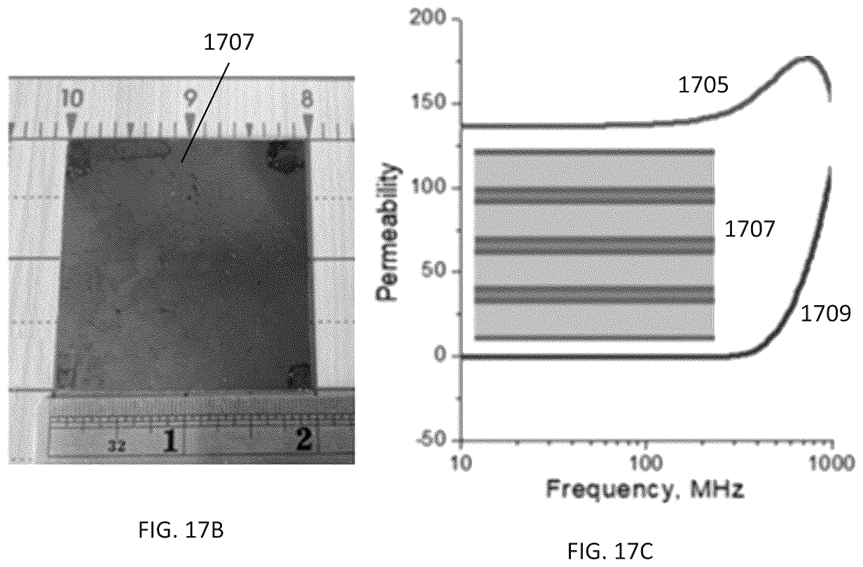

It is difficult to deposit magnetic films in via holes by conventional methods, but it is relatively easy to do it by spin spray deposition. FIG. 17B shows a uniform 3 μm thick film of Mn—Zn ferrites was coated into the via holes on PCB with spin-spray methods, indicating that the fabrication of via inductors by spin-spray methods is feasible. Further, the designs of the inductors can be further improved with more 3 μm ferrite loops, which can be readily implemented by one spin-spray deposition process and new mask design. This is an entirely new approach to fabricate ferrite via-based inductors for WBG/UWBG power electronics, and currently the whole industry has been unable to do.

The new integrated ferrite inductors enabled by spin spray deposited ferrites result in new integrated ferrite inductors with 300 MHz or higher cut-off frequency.

FIG. 17A-17C show the magnetic permeability of two examples of ferrite PCBs of different thicknesses. FIG. 17A shows the relative permeability spectrum (real and imaginary) of a ferrite PCB coated with 3 μm MnZn-ferrite film. 1701 numeral number represents the real part of the relative permeability over frequency, 1700 numeral number represents the imaginary part of the relative permeability The real part of the permeability is over 3000 while the imaginary remains around zero in frequency range less than 400 MHZ.

FIG. 17B is a picture of a hot-pressed 0.65 mm thick magnetic PCB with a size of 2″×2″×0.65 mm by hot-pressing a 3 μm MnZn-ferrite/100 μm PCB/3 μm MnZn-ferrite with 50 μm thick epoxy or prepreg at 120° C. for 30 minutes. 1707 numeral in FIG. 17C illustrates the sectional view of the 0.65 mm thick magnetic PCB of FIG. 17B. FIG. 17C is a relative permeability spectrum of the 0.65 mm thick magnetic PCB, 1705 numeral number represents the real part of the relative permeability over frequency, 1709 numeral number represents the imaginary part of the relative permeability. The real part of the permeability is over 135 while the imaginary remains around zero in frequency range of cut-off frequency of ˜400 MHz.

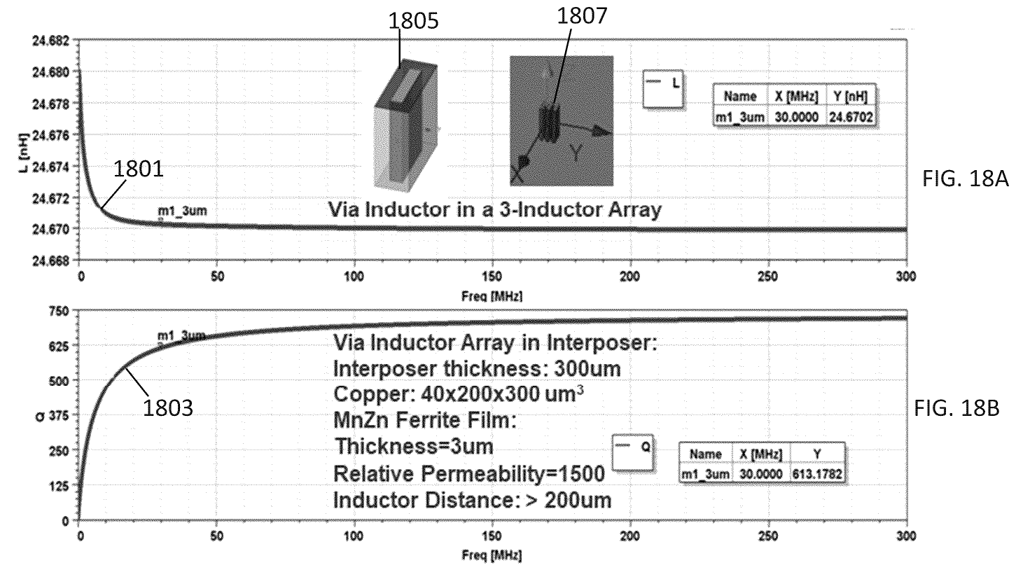

The first type is a via-based inductor array design in an interposer for 3D heterogeneously integrated power electronics. FIG. 18A-18B show Maxwell3D simulated via-based ferrite inductor inductances L and quality factors Q over frequency in a 3-inductor array integrated into a 300 μm-thick interposer, enabled by a 3 μm thick spin spray deposited ferrite with a reduced relative permeability of 1500. The via inductor array shows an inductance of 24.67 nH and high Q >625 at 50˜300 MHz, both are over 10 times better than currently best-reported data.

Table 1 shows parameter comparisons between the ferrite via-inductor fabricated by the spin-spray methods in this application and other inductors fabricated by Intel Corporation. indicates that these new, spin-sprayed method manufactured, compact ferrite via-based inductors on a 300 μm thick interposers with a 3 μm thick spin spray deposited Mn—Zn ferrite have a high inductance of L=24.7 nH, low DC resistance R_{DC}=1.3 mΩ, high quality factor Q >700, and 5˜10 A current handling capabilities. This set of specifications is the best, far better than the rest of the reported inductors, including the ones used in the recent products of Intel Corporation.

TABLE 1
Ferrite Via Inductor through Spin Spray in Comparison with the Magnetic
Inductors for WBG/UWBG Power Electronics from Intel Corporation.

| Inductor | Ferrite Via Inductor | | Composite | | Alr Core | | Composite | | Composite | | Thin Film | | Thin Film | |
|---|---|---|---|---|---|---|---|---|---|---|---|---|---|---|
| Metric | (Our work) | | Core | | Inductor | | Core | | Core | | Magnetics | | Magnetics | |
| Inductance | 24 | nH | 2.5 | nH | 1.2 | nH | 3.0 | nH | 374 | nH | 3.9 | nH | 120 | nH |
| R_{dc} | 1.29 | mΩ | 12 | mΩ | 7 | mΩ | 12 | mΩ | 24 | mΩ | 39 | mΩ | 270 | mΩ |
| Iₘₐₓ | 5 | A | 8 | A | 8 | A | 4 | A | 2.5 | A | 1.25 | A | 0.4 | A |
| L/R_{dc} | 18604 | nH/Ω | 208 | nH/Ω | 171 | nH/Ω | 250 | nH/Ω | 1558 | nH/Ω | 100 | nH/Ω | 444 | nH/Ω |
| Area | 0.36 | mm² | 0.4 | mm² | 2 | mm² | 0.5 | mm² | 6 | mm² | 0.5 | mm² | 0.9 | mm² |
| Iₘₐₓ/Area | 13.9 | A/mm² | 20 | A/mm² | 4 | A/mm² | 8 | A/mm² | 0.41 | A/mm² | 2.5 | A/mm² | 0.44 | A/mm² |
| Energy/Area | 833.3 | nJ/mm² | 200 | nJ/mm² | 19.2 | nJ/mm² | 48 | nJ/mm² | 195 | nJ/mm² | 6.1 | nJ/mm² | 10.7 | nJ/mm² |

| | | | | | | | |
|---|---|---|---|---|---|---|---|
| Peak Q (f) | 625 (300 MHz) | 33 (90 MHz) | 24 (140 MHz) | 18 (100 MHz) | 29 (10 MHz) | 15 (100 MHz) | 14.5 (15 MHz) |

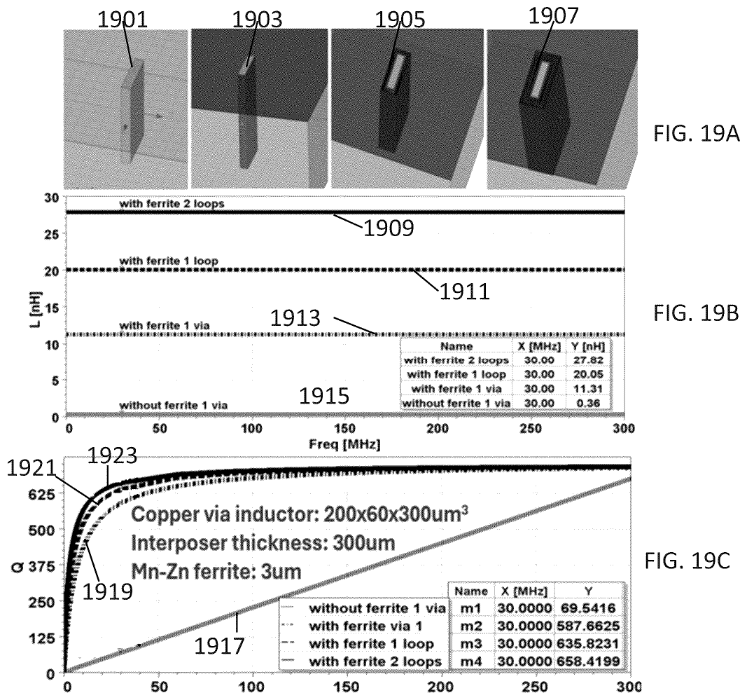

FIG. 19A shows four types of copper via-based inductors: Numeral 1901 illustrates a 200×60×300 μm³ copper via-based inductor without ferrite; Numeral 1903 illustrates a 200×60×300 μm³ copper via-based inductor with 3 μm ferrite films on top and bottom of PCB interposer, numeral 1905 illustrates a 200×60×300 μm³ copper via-based inductor with 3 μm ferrite films on top and bottom of PCB interposer and one 3 μm ferrite loop; numeral 1907 illustrates a 200×60×300 μm³ copper via-based inductor with 3 μm ferrite films on top and bottom of PCB interposer with two 3 μm ferrite loops. All four kinds of inductors can be made by one spin spray deposition of 3 μm Mn—Zn ferrite films, the spin spray deposition of ferrite rings around the Cu via inductor was confirmed. HFSS was simulated with these via-based inductors. FIG. 19B shows the inductances and FIG. 19C shows the Q factors. The inductances of the via inductors with ferrite coating (1913), ferrite coating plus one ferrite loop (1911) and ferrite coating plus two ferrite loops (1909) range from 11 to 28 nH, which are 36 times to 93 times enhanced over that of via inductor without ferrite (1915) that only shows an inductance of 0.3 nH. Also, these ferrite via inductors show a high Q >700 at 100˜300 MHz (referred by numerals 1919, 1921, 1923 respectively). Compared to that of via inductor without ferrite (referred by numeral 1917), these Q factors are more than 20 times better than the currently best-reported data.

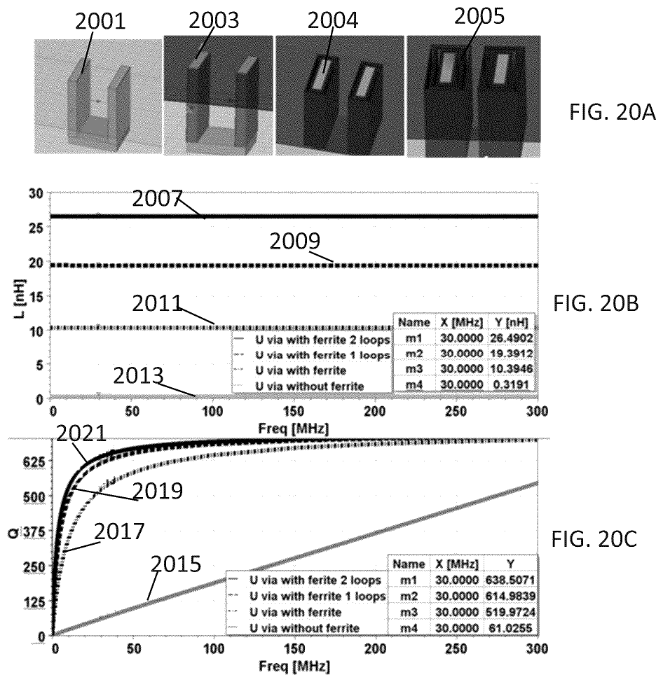

FIG. 20A shows four types of U shaped copper via-based inductors: Numeral 2001 illustrates a 200×60×300 μm³ U shaped copper via-based inductor without ferrite; Numeral 2003 illustrates a 200×60×300 μm³ U shaped copper via-based inductor with 3 μm ferrite films on top and bottom of PCB interposer, numeral 2004 illustrates a 200×60×300 μm³ U shaped copper via-based inductor with 3 μm ferrite films on top and bottom of PCB interposer and one 3 μm ferrite loop; numeral 2005 illustrates a 200×60×300 μm³ U shaped copper via-based inductor with 3 μm ferrite films on top and bottom of PCB interposer with two 3 μm ferrite loops. All four kinds of inductors can be made by one spin spray deposition of 3 μm Mn—Zn ferrite films, the spin spray deposition of ferrite rings around the Cu via inductor was confirmed. HFSS was simulated with these via-based inductors. FIG. 20B shows the inductances and FIG. 20C shows the Q factors. The inductances of the via inductors with ferrite coating (2011), ferrite coating plus one ferrite loop (2009) and ferrite coating plus two ferrite loops (2007) range from 10 to 26 nH, which are 33 times to 83 times enhanced over that of via inductor without ferrite (2013) that only shows an inductance of 0.32 nH. Also, these ferrite via inductors show a high Q >519 at 100˜300 MHz (referred by numerals 2017, 2019, 2021 respectively). Compared to that of via inductor without ferrite (referred by numeral 2015), these Q factors are more than 15 times better than the currently best-reported data.

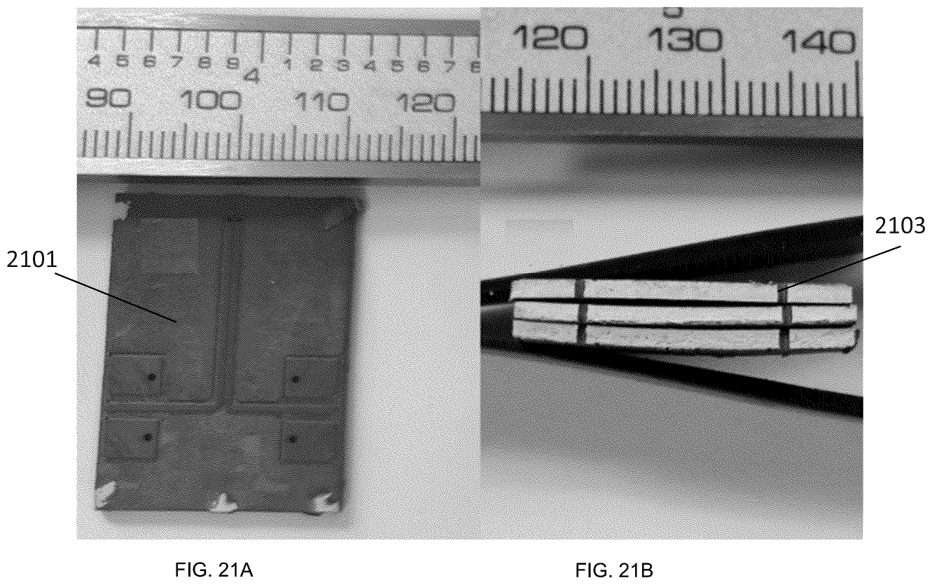

In reference to FIG. 21, numeral 2101 is a photo of a 3 μm spin spray Mn—Zn ferrite coated PCB of 1 mm thick with via holes; 2103 is the dark ferrites in the via holes after the via holes were cut open.

An example set of processes for manufacturing a via-based ferrite inductor on Si substrate and transformer includes following steps:
Step 1: conducting photolithography and DRIE (Deep Reactive Ion Etching) on Si substrate to generate via openings using 200˜300 μm thick Si substrates, such as high resistance Si wafer;
Step 2: conducting spin spray ferrite depositions on both sides of the wafer;
Step 3: conducting copper seed-layer deposition into the vias from both sides;
Step 4: conducting electrodeposition of copper.

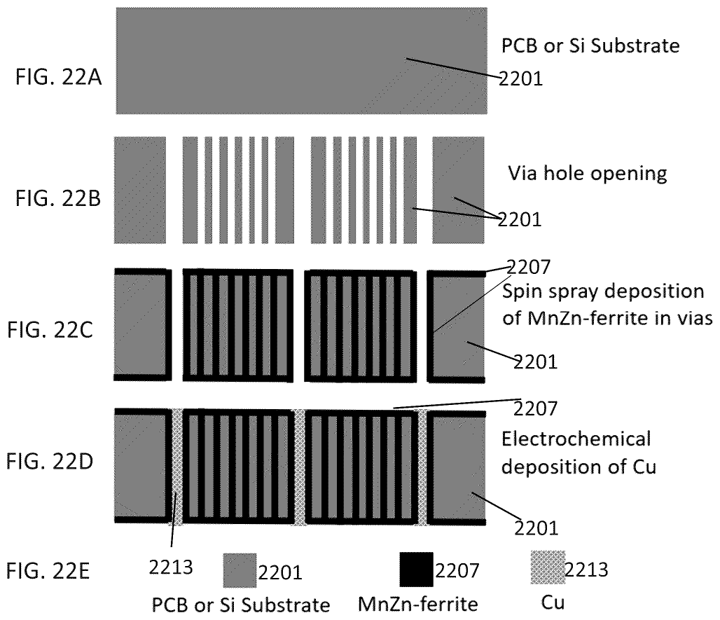

FIG. 22A to FIG. 22E illustrate an example process for fabricating an I-shaped ferrite via-based inductor. In FIG. 22E are the shaded patterns used in the schemes in FIG. 22A to FIG. 22D. 2201 pattern represents PCB or Si substrates, 2207 pattern represents MnZn-ferrite, 2213 pattern represents copper deposit. In FIG. 22A is an unprocessed PCB or Si substrate 2201. Substrate 2201 is processed by photolithography and DRIE to generate via-openings 2202, 2204 generating a structure in substrate 2201 with sectional view shown in FIG. 22B. The substrate in FIG. 22B is then spin-sprayed on both sides with a 3 μm thick of MnZn ferrite film 2207 deposited to the entire surface area of the substrate, including the via-openings 2202, 2204, generating a coated substrate with a sectional view in FIG. 22C. The substrate in FIG. 22C is used to further deposit copper seed layer and for copper electrodeposition, generating an inductor with a sectional view shown in FIG. 22D. where copper element 2213 is deposited to the wider openings 2204 while the narrower openings 2202 may be fully filled with ferrite deposits, forming ferrite loops.

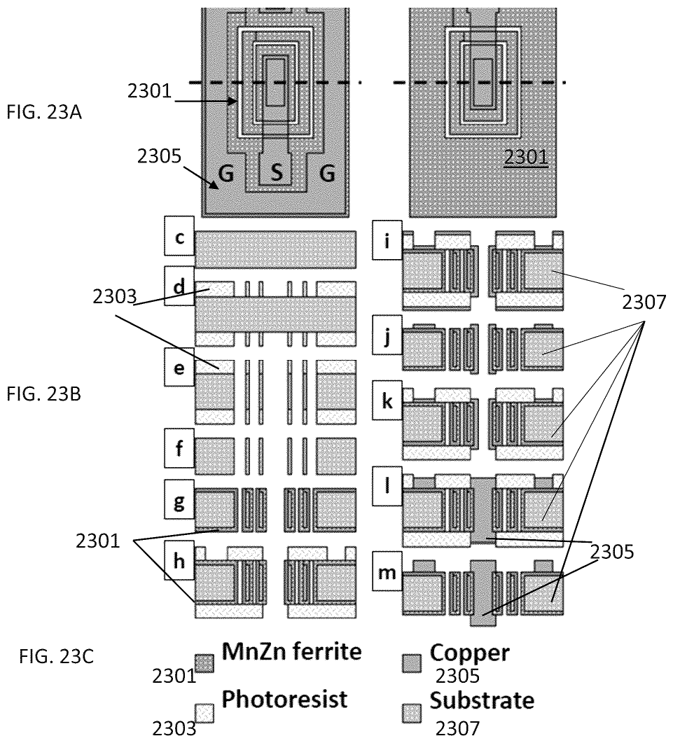

Similarly, FIG. 23A to FIG. 23C illustrate an example process for fabricating U-shaped ferrite via-based inductors where copper is deposited to U shaped copper connection with different ferrite coating patterns on each side of the substate as shown in FIG. 23A. In FIG. 23B are the shaded patterns used in the schemes in FIG. 23A to FIG. 23B. 2307 pattern represents PCB or Si substrates, 2301 pattern represents MnZn-ferrite, 2305 pattern represents copper deposit, and 2303 pattern represents photoresist coating. In FIG. 23B, step c is an unprocessed PCB or Si substrate 2307. Substrate 2307 is processed by photolithography or DRIE to generate none-through grooves 2302, 2304, generating a structure in substrate with sectional view shown step d. At step d, the outer area is then deposited a layer of photoresist material 2303; at step e, the substrate is further processed with photolithography or DRIE methods to generate complete openings 2306, 2308, 2310 with different widths. At step f, photoresist material 2303 is removed, generating a structure of sectional view in f. At step g, the entire open surface of substrate 2307 is deposited with a layer of MnZin ferrite 2301 by spin-spray method. At step h, a further patterned photoresist material 2303 is deposited to protect opening 2310. At step i, copper seed layers are deposited to unprotected areas 2312 and 2314. At step j, the photoresist protective layer is removed, generating a structure with sectional view shown in j. At step k, photoresist protective layer is again laid to protect openings 2310. At step I, copper element 2305 is electrodeposited to opening 2308. At step m, the photoresist protective layer is removed, generating a U-shaped copper inductor with multiple ferrite loops, with a sectional structure shown in m of FIG. 23B.

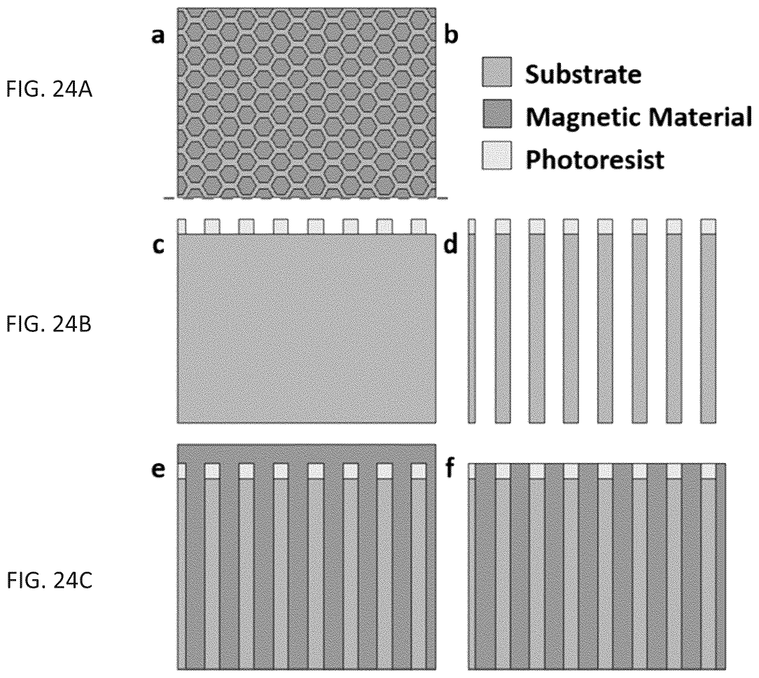

Similarly, FIG. 24A to FIG. 24C illustrate an example process for fabricating hexagonal array ferrite vias-based inductors.

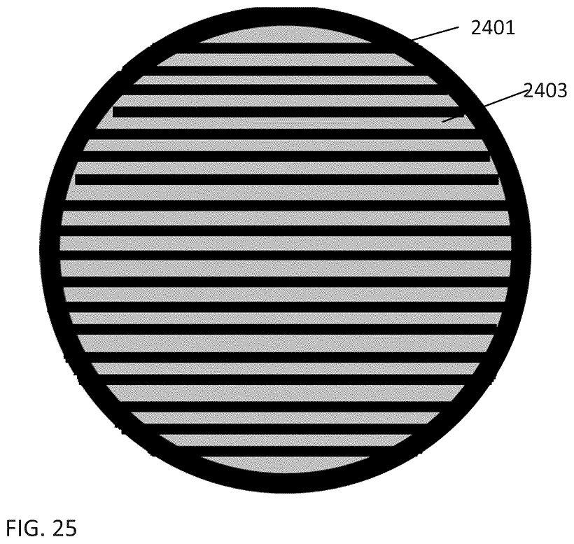

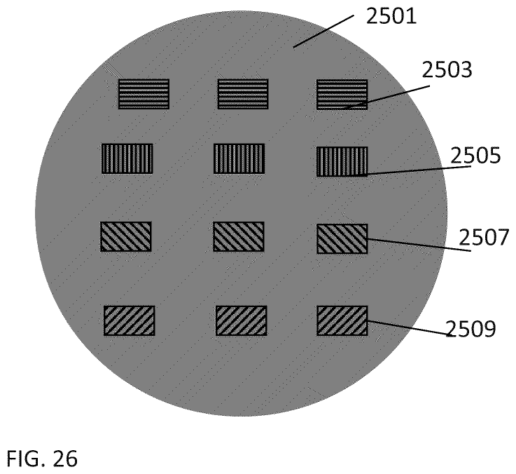

In reference to FIG. 25, via openings may be formed with one direction on an entire wafer substrate including PCB, glass, Si, SiC, GaN, GaAs, AlN, BN etc. In reference to FIG. 26, via openings or grooves with different directions may be formed on different sections of a wafer substrate, including PCB, glass, Si, SiC, GaN, GaAs, AlN, BN, etc.

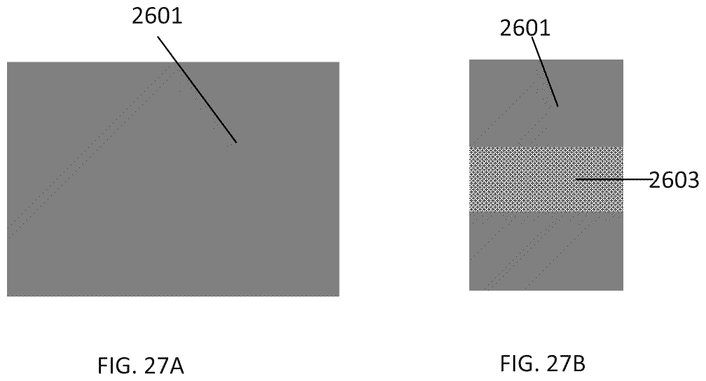

In reference to FIG. 27A and FIG. 27B, a via inductor without ferrite coating on substrate is shown. FIG. 27A is a front view and FIG. 27B is a side sectional view that shows the substrate material 2601 and copper material 2603.

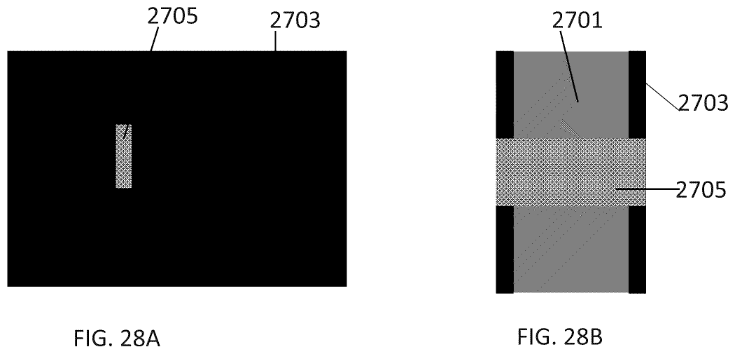

In reference to FIG. 28A and FIG. 28B, a via inductor ferrite coating on substrate is shown. FIG. 28A is a front view and FIG. 28B is a side sectional view that shows the substrate material 2701 and copper material 2705 and ferrite coating 2703.

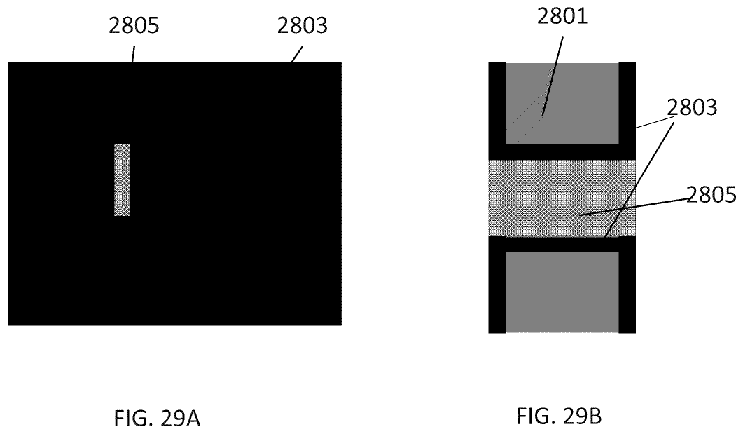

In reference to FIG. 29A and FIG. 29B, a via inductor with ferrite coating and one ferrite loop on substrate is shown. FIG. 29A is a front view and FIG. 29B is a side sectional view that shows the substrate material 2801 and copper material 2805 and ferrite coating 2803. Ferrite coating 2803 also loops around the copper.

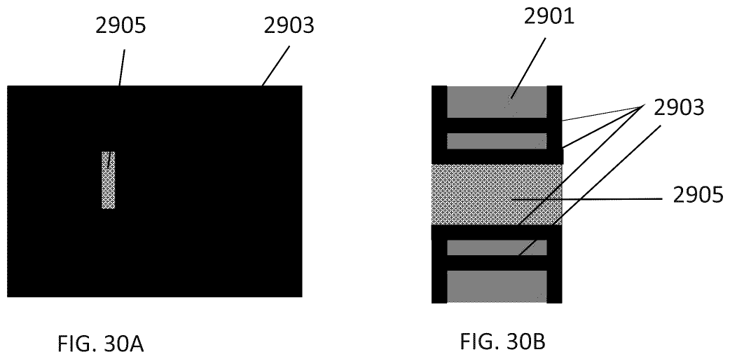

In reference to FIG. 30A and FIG. 30B, a via inductor with ferrite coating and two ferrite loops on substrate is shown. FIG. 30A is a front view and FIG. 30B is a side sectional view that shows the substrate material 2901 and copper material 2905 and ferrite coating 2903. Ferrite coating 2903 also forms two loops around the copper.

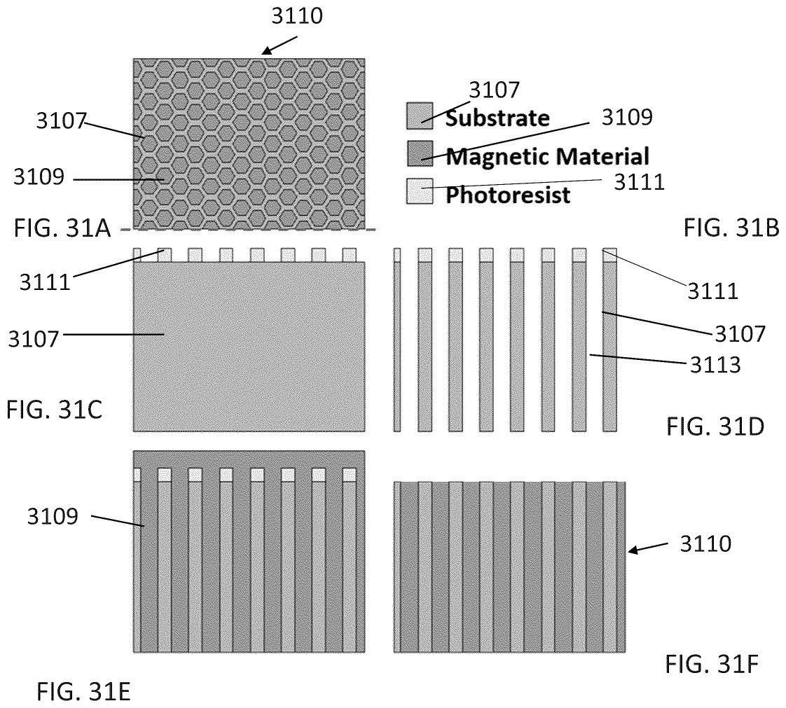

In reference to FIG. 31A to FIG. 31F, a hybrid magnetic-substrate design is presented and described. FIG. 31A shows a top view of hybrid substrate 3110 where substrate material 3107 forms a three-dimensional beehive structure and the beehive space is filled with magnetic material 3109 as shown in sectional view FIG. 31F. Other patterns of hybrid magnetic substrate may be designed and fabricated according to need. The fabrication process may include a photolithography or DRIE process where a photo masking process is performed by first depositing photoresist material 3111 onto substrate 3107 according to a pre-designed patten (FIG. 31C). The unprotected areas of the substrate are further etched away through etching, chemical vapor deposition, or ion implantation processes, generating patterned openings 3113 and patterned substrate 3107 (FIG. 31D). The patterned substrate is further deposited with magnetic material through the sin-spray method described in this application (FIG. 31E). magnetic material filled substrate is further processed to remove the photoresist coating. This usually requires a liquid “resist stripper”, which chemically alters the resist so that it no longer adheres to the substrate. Alternatively, the photoresist may be removed by a plasma containing oxygen, which oxidizes it. The use of 1-Methyl-2-pyrrolidone (NMP) solvent for photoresist is another method. When the resist has been dissolved, the solvent can be removed by heating to 80° C. without leaving any residue.

The vertical layered laminate structure forming magnetic substrate, with ˜1000 magnetic relative permeability. The process is cost efficient and can be implemented with one spin spray deposition process. Substrate integrated ferrite inductors, transformers, filters, antennas, phase shifters of a system may be manufactured in large quantity for simplified 3D heterogeneous integration. The process reduces the number of surface mount inductors and transformers with lower profile, more compact and more power efficient. This process enabled simplified system with chiplet approach. Multiple shape and depth of grooves may be cut on one wafer with varying depths of the grooves.

Substrate material includes PCB, glass, Si, SiC, GaN, GaAs, AlN, BN and any other suitable materials that may be developed in the future. Multiple ferrite loops may be constructed around the copper deposit.

Having described at least one of the preferred embodiments of the present invention with reference to the accompanying drawings, it will be apparent to those skills that the invention is not limited to those precise embodiments, and that various modifications and variations can be made in the presently disclosed system without departing from the scope or spirit of the invention. Thus, it is intended that the present disclosure covers modifications and variations of this disclosure provided they come within the scope of the appended claims and their equivalents.

Additional general background, which helps to show variations and implementations, may be found in the following publications, all of which are hereby incorporated by reference herein for all purposes:
1. “Antennas”, Kraus, J. D. 2nd Ed, MacGraw Hill, 1988;
2. “Broadband Ferrite Loaded Loop Antenna”, Meloling John Harold, Dawson David Carlos, Hansen Peder Meyer, U.S. Pat. No. 7,737,905, 2010;
3. “Ferrite Antenna”, Huf Huelsbeck, Fuerst G, and Neosid Pemetzrieder, U.S. Pat. No. 6,919,856, 2005;
4. “Twin coil antenna”, Christopher M. Justice, U.S. Pat. No. 6,529,169, 2003;
5. U.S. patent application Ser. No. 17/503,873, entitled “Millimeter thick magnetic print circuit boards (PCBs) with a high relative permeability of 50˜150 and related devices and systems” by Xiaoling Shi, Hui Lu, Nian Xiang Sun, Winchester Technologies, LLC, Burlington, MA 01803,
6. Manual of the RFMAG26 FMR spectrometer and Permeameter system developed by the inventors, and commercialized by Winchester Technologies, LLC, https://winchestertech.com/wp-content/uploads/2019/08/RFmag.pdf.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle. The claims as filed are intended to be as comprehensive as possible, and NO subject matter is intentionally relinquished, dedicated, or abandoned.

1. A method for generating a magnetic substrate, comprising the steps of:
providing a spin-spray machinery having a first spray nozzle, a second spray nozzle, a spindle platform for spinning and heating a substrate;
spraying the substrate with a ferrite ion reaction solution from the first spray nozzle at a first spraying speed;
simultaneously spraying the substrate with an oxidant buffer solution from the second spray nozzle at a second spraying speed;
simultaneously spinning said substrate at a rotation speed between about 5 rpm to about 1000 rpm while simultaneously heating said substrate to a temperature between 20° C. to 100° C. to form a ferrite film with a thickness in the range of 50 nm to 20 μm;
collecting a first ferrite-coated substrate; and
resulting in a magnetic substrate that has ferromagnetic resonance in the range of 5 to 5000 MHz and a tunable magnetic relative permeability greater than 650 and a high saturation magnetization greater than 0.1 T, and a magnetic loss tangent (the ratio of its Imaginary permeability over its Real permeability) less than 10%.

2. The method of claim 1, wherein the first and the second spraying speed is between 1 ml/min to 1000 ml/min.

3. The method of claim 1, wherein said first and second nozzles are placed directly over the substrate with a distance between the nozzles and the substrate's surface in a range of about 1 inch to about 50 inches.

4. The method of claim 1, wherein the step of spraying lasts between 1 minute and 1000 minutes.

5. The method of claim 1, wherein the ferrite ion reaction solution comprises FeCl₂ and metal salts MCI₂, where M represents a metal ion selected from Zn, Co, Mn, Cu, Ni and a mixture thereof, and the oxidizing solution is an oxidant NaNO₂ or KNO₂ in an acetate buffer.

6. The method of claim 1, wherein the first ferrite-coated substrate has a different ferrite composition from the ferrite composition of the second ferrite-coated substrate.

7. The method of claim 1, wherein the magnetic substrate has a total thickness between 0.05 mm to 12 mm.

8. The method of claim 1, further comprising a step of:
first conducting photolithography or DRIE (Deep Reactive Ion Etching) process on said substrate to generate via openings on said substrate.

9. The method of claim 1, wherein said substrate comprises organic material PCB, organic flexible, glass, Si, SiC, GaN, GaAs, AlN, or BN.

10. The method of claim 1, further comprising the steps of:
generating one to more second ferrite coated substrates by dividing said first ferrite-coated substrate or by repeating the coating process on another substrate;
stacking said first ferrite coat substrate and said one or more second ferrite coated substrates over each other into a stack, with a layer of thermoset resin;
hot-pressuring said ferrite-coated substrate stack with a pressure between 0.01 psi to 100 psi at a temperature between 50° C.˜400° C. for 1 min to 24 hrs; and
resulting in a magnetic substrate that has ferromagnetic resonance in the range of 5 to 5000 MHz and a tunable magnetic relative permeability greater than 300 and a high saturation magnetization greater than 0.1 T, and a magnetic loss tangent (the ratio of its Imaginary permeability over its Real permeability) less than 10%.

11. A method for fabricating a ferrite via-based inductor on a substrate using the method of claim 1, comprising the steps of:
generating via-openings on said substrate to obtain a substrate with one or more via-openings;
providing spin-spray machinery having a first spray nozzle, a second spray nozzle, and a spindle platform for spinning and heating a substrate;
spraying the substrate with via-openings with a ferrite ion reaction solution from the first spray nozzle at a first spraying speed;
simultaneously spraying the substrate with via-openings with an oxidant buffer solution from the second spray nozzle at a second spraying speed;
simultaneously spinning said substrate with via-openings at a rotation speed between about 5 rpm to about 1000 rpm while simultaneously heating said substrate with via-openings to a temperature between 20° C. to 300° C. to form a ferrite film with a thickness in the range of 50 nm to 20 μm;
collecting a first ferrite-coated substrate with a ferrite-coated via-opening;
conducting copper seed-layer depositions into said ferrite-coated via opening;
micro-patterning of a photoresist layer for defining integrated magnetic devices, such as inductors or transformers; and
conducting electrodeposition of copper element into said ferrite coated via-openings.

12. The method of claim 11 wherein said via-openings comprises a plurality of via-openings designed with multiple sizes ranging from 50 nm to 5000 μm and said ferrite coating fills one or more of said plurality via-openings to form ferrite loops.

13. The method of claim 12, the step of generating via-openings on said substrate comprises a step of photoresist coating before the step of photolithography or DRIE process.

14. The method of claim 13, further comprising a step of photoresist coating before the step of spraying of ferrite coating to protect a particular via-opening from coating ferrites.

15. The method of claim 14, further comprising a step of photoresist coating after the step of spraying of ferrite coating of said via-openings to protect a particular via-opening from subsequent processes.

16. The method of claim 15, further comprising the step of repeating the steps of photoresist coating before and after the step of spraying of ferrite coating of said via-openings to produce a particular ferrite coating pattern.

17. The method of claim 16, further comprising the step of generating a U shaped via-based ferrite inductor.

18. The method of claim 13, further comprising the step of generating hexagonal array vias-based ferrite inductor.

19. The method of claim 11, further comprising the step of generating one or more I shaped ferrite structures.

20. The method of claim 11, wherein said substrate comprises a material comprising organic material PCB, organic flexible, glass, Si, SiC, GaN, GaAs, AlN, or BN.

21. A method for fabricating a hybrid magnetic substrate having a particular ferrite-coated slit-opening pattern using the method of claim 1, comprising the steps of:
conducting a first photoresist coating on said substrate with a first schematic slit pattern;
constructing the first schematic slit pattern on said substrate;
providing spin-spray machinery having a first spray nozzle, a second spray nozzle, and a spindle platform for spinning and heating a substrate;
spraying said substrate having the first schematic slit pattern with a ferrite ion reaction solution from the first spray nozzle at a first spraying speed;
simultaneously spraying said substrate having the first schematic slit pattern with an oxidant buffer solution from the second spray nozzle at a second spraying speed;
simultaneously spinning said substrate having the first schematic slit pattern at a rotation speed between about 5 rpm to about 1000 rpm while simultaneously heating said substrate to a temperature between 20° C. to 300° C. to form a ferrite film with a thickness in the range of 50 nm to 20 μm; and
collecting a first hybrid magnetic substrate with the ferrite-coated first schematic slit pattern.

22. The method of claim 21, further comprising the steps of:
conducting a second photoresist coating on said substrate with the first schematic slit pattern with a second schematic slit pattern before spraying ferrite coating.

23. The method of claim 21, further comprising the steps of:
conducting a second photoresist coating on said substrate with the first schematic split pattern with a second schematic slit pattern after spraying ferrite coating; and
constructing the second schematic slit pattern on said first substrate with the ferrite coated first schematic slit pattern.

24. The method of claim 23, further comprising the steps of:
spraying the substrate with the second schematic pattern with a ferrite ion reaction solution from the first spray nozzle at a first spraying speed;
simultaneously spraying the substrate with the second schematic pattern with an oxidant buffer solution from the second spray nozzle at a second spraying speed;
simultaneously spinning said substrate at a rotation speed between about 5 rpm to about 1000 rpm while simultaneously heating said substrate to a temperature between 20° C. to 100° C. to form a ferrite film with a thickness in the range of 50 nm to 20 μm; and
collecting a second hybrid substrate with the ferrite coated combination of first schematic slit pattern and second slit pattern.

25. The method of claim 21, wherein the substrate is a wafer.

26. The method of claim 21, wherein the first schematic slit pattern is that of a beehive pattern.

27. A method for manufacturing ferrite via-based inductors using the method of claim 1, comparing the step of:
generating inductors using the method of claim 21, wherein the ferrite via-based inductors have a Quality Factor bigger than 625 at 50˜300 MHz.

28. A method for manufacturing ferrite via-based transformers using the method of claim 1, comparing the steps of
generating transformers using the method of claim 21, wherein the ferrite via-based inductors have a Quality Factor bigger than 625 at 50˜300 MHz.

29. A ferrite via-based inductor manufactured by the method of claim 21, wherein the ferrite via-based inductors have Quality Factors bigger than 625 at 50˜300 MHz.

30. The ferrite via-based inductor of claim 29 is further processed by the method of claim 23, wherein the ferrite via-based inductors have a Quality Factor bigger than 625 at 50˜300 MHz.

31. A ferrite via-based transformer manufactured by the method of claim 21, wherein the ferrite via-based transformers have Quality Factors bigger than 625 at 50˜300 MHz.

32. The ferrite via-based transformers of claim 31 is further processed by the method of claim 23 wherein the ferrite via-based transformers have Quality Factors bigger than 625 at 50˜300 MHz.
